(19) United States
(12) Patent Application Publication
(10) Pub. No.: US 2025/0380458 A1
(43) Pub. Date: Dec. 11, 2025

(54) Different Sacrificial Layers for Different Type Devices

(71) Applicant: Taiwan Semiconductor Manufacturing Company, Ltd., Hsin-Chu (TW)

(72) Inventors: Bwo-Ning CHEN, Keelung City (TW); Chun-Fai CHENG, Shui Wai (HK); Chi-An WANG, Hsinchu City (TW); Chang-Miao LIU, Hsinchu City (TW)

(21) Appl. No.: 18/941,253

(22) Filed: Nov. 8, 2024

Related U.S. Application Data
(60) Provisional application No. 63/656,737, filed on Jun. 6, 2024.

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 64/018; H10D 84/0128; H10D 84/013; H10D 84/0135; H10D 84/038; H10D 84/83

(57) ABSTRACT

Methods of fabricating different type multigate transistors using different sacrificial layers, such as dummy semiconductor interposers (DSI) for n-type multigate transistors and dummy oxide interposers (DOI) for p-type multigate transistors, are disclosed herein. An exemplary method includes masking an n-type transistor region when forming DOIs in a p-type transistor region and gaps for inner spacers in the p-type transistor region (e.g., formed by recessing the DOIs), masking the p-type transistor region when forming gaps for inner spacers in the n-type transistor region (e.g., formed by recessing the DSIs), and forming the inner spacers in the gaps in the p-type transistor region and the gaps in the n-type transistor region simultaneously or separately. The method may include, during a gate replacement process, masking the n-type transistor region when removing the DOIs in the p-type transistor region and masking the p-type transistor region when removing the DSIs in the n-type transistor region.

This is a non-provisional application of and claims benefit of U.S. Provisional Patent Application Ser. No. 63/656,737, filed Jun. 6, 2024, the entire disclosure of which is incorporated herein by reference.

### BACKGROUND

Recently, multigate devices, which have gates that extend, partially or fully, around a channel to provide access to the channel on at least two sides, have been introduced to improve gate control. Exemplary multigate devices include fin-like field effect transistors (FinFETs) and gate-all around (GAA) transistors, such as nanowire transistors. Multigate devices enable aggressive scaling down of integrated circuit (IC) technologies, maintaining gate control, and mitigating short-channel effects (SCEs), while seamlessly integrating with conventional IC manufacturing processes. As multigate devices continue to scale, advanced techniques are needed for optimizing multigate device reliability and/or performance.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method, in portion or entirety, for fabricating gate stacks of different type transistors, according to various aspects of the present disclosure.

FIGS. 2-22 are cross-sectional views of a device, in portion or entirety, at various fabrication stages of the method in FIG. 1, according to various aspects of the present disclosure.

FIG. 23 is a top view of the device, in portion or entirety, at the fabrication stage corresponding with FIG. 22, according to various aspects of the present disclosure.

FIGS. 24-27 are various cross-sectional views of the device, in portion or entirety, of FIG. 22 and FIG. 23, according to various aspects of the present disclosure.

FIG. 28 is a cross-sectional view of portions of the device, in portion or entirety, of FIG. 22, according to various aspects of the present disclosure.

### DETAILED DESCRIPTION

The present disclosure relates generally to multigate devices and methods of fabrication thereof, and more particularly, to gate replacement techniques for multigate devices.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

As integrated circuit (IC) technologies progress towards smaller technology nodes, multigate devices, such as multigate metal-oxide-semiconductor field effect transistors (MOSFETs), have been introduced to improve gate control by increasing gate-channel coupling, reducing off-state current, and reducing short-channel effects (SCEs). A multigate device generally refers to a device having a gate, or portion thereof, disposed over more than one side of a channel. Gate-all-around (GAA) transistors (e.g., nanowire transistors, nanosheet transistors, fork-sheet transistors, and the like) are examples of multigate devices that have become popular and promising candidates for high performance and low leakage applications. A GAA transistor has a gate that extends, partially or fully, around a channel to provide access to the channel on two or more sides. Because the gate may surround the channel(s), a GAA transistor may also be referred to as a surrounding gate transistor or a multi-bridge-channel transistor.

As GAA transistors continue to scale, challenges have arisen. For example, GAA transistors may be fabricated using a replacement gate process, where a dummy gate stack is formed first as a placeholder and is subsequently replaced with a functional gate stack. In some replacement gate processes, sacrificial materials provided in the channel region of a GAA transistor are removed by an etching process after source/drain formation and replaced with the functional gate stack. In the GAA transistor, the sacrificial materials may be disposed between channel materials, and the etching process selectively removes the sacrificial materials relative to the channel materials, such that the channel materials remain in the channel region to provide one or more channels (e.g., silicon nanostructures and/or silicon germanium nanostructures) of the GAA transistor. The sacrificial materials may be referred to as sheet interposers. During the removal of the sacrificial materials, inner, dielectric spacers may function to contain the etching process to define and/or maintain a profile of the functional gate stack and/or to protect the previously formed source/drains from being damaged during the etching process.

The present disclosure recognizes that the sacrificial materials impact GAA transistor performance and proposes different sacrificial materials for different type GAA transistors to optimize GAA device performance. For example, disposable/dummy semiconductor interposers (DSIs), such as silicon germanium layers, provide stress to the channel materials, such as the silicon layers, that may improve performance of an n-type GAA transistor (e.g., less channel resistance (Rch)) but degrade performance of a p-type GAA transistor. Conversely, disposable/dummy oxide interposers (DOIs), such as oxide layers, do not impart stress to the channel materials, which may improve performance of a p-type GAA transistor (e.g., less channel resistance) but degrade performance of an n-type GAA transistor. The present disclosure thus provides methods of fabricating different type GAA transistors using different sacrificial layers, such as DSI for n-type GAA transistors and DOI for p-type GAA transistors.

An exemplary method includes masking an n-type transistor region when forming DOIs in a p-type transistor region and gaps for inner spacers in the p-type transistor region (where the gaps for the inner spacers may be formed by recessing the DOIs), masking the p-type transistor region when forming gaps for inner spacers in the n-type transistor region (where the gaps for the inner spacers may be formed by recessing DSIs), and forming the inner spacers in the gaps in the p-type transistor region and the gaps in the n-type transistor region simultaneously or separately. The method may further include masking the n-type transistor region when performing a channel release process in the p-type transistor region (e.g., selectively removing the DOIs relative to silicon layers in the p-type transistor region) and masking the p-type transistor region when performing a channel release process in the n-type transistor region (e.g., selectively removing the DSIs, such as silicon germanium layers, relative to silicon layers in the n-type transistor region). A gate dielectric may be formed in the p-type transistor region over the channels in the p-type transistor region after the channel release process while the n-type transistor region is masked, and a gate dielectric may be formed in the n-type transistor region over the channels in the n-type transistor region after the channel release process while the p-type transistor region is masked. In other words, the gate dielectrics may be formed separately for the p-type transistor region and the n-type transistor region. Implementing DSIs in the n-type transistor region imparts stress (e.g., tensile stress) to channels of an n-type GAA transistor that may boost its performance, while performance of a p-type GAA transistor is maintained by implementing DOIs in the p-type transistor region. Different embodiments may have different advantages, and no particular advantage is required of any embodiment.

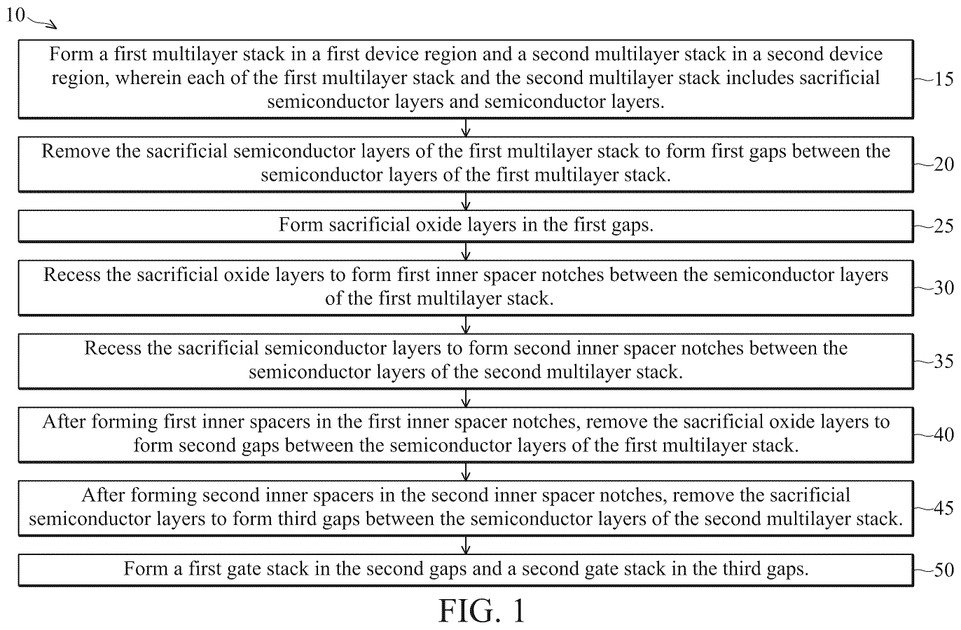

FIG. 1 is a flow chart of a method 10, in portion or entirety, for fabricating gate stacks of different type transistors using different sacrificial layers, according to various aspects of the present disclosure. At block 15, method 10 includes forming a first multilayer stack in a first device region (e.g., a p-type multigate transistor region) and a second multilayer stack in a second device region (e.g., an n-type multigate transistor region). Each of the first multilayer stack and the second multilayer stack includes sacrificial semiconductor layers (e.g., silicon germanium layers) and semiconductor layers (e.g., silicon layers). Method 10 further includes removing the sacrificial semiconductor layers of the first multilayer stack to form first gaps between the semiconductor layers of the first multilayer stack at block 20, forming sacrificial oxide layers (e.g., silicon oxide layers) in the first gaps at block 25, and recessing the sacrificial oxide layers to form first inner spacer notches between the semiconductor layers of the first multilayer stack at block 30. At block 35, method 10 includes recessing the sacrificial semiconductor layers to form second inner spacer notches between the semiconductor layers of the second multilayer stack. At block 40, method 10 includes removing the sacrificial oxide layers to form second gaps between the semiconductor layers of the first multilayer stack. The sacrificial oxide layers are removed to form the second gaps after forming first inner spacers in the first inner spacer notches. At block 45, method 10 includes removing the sacrificial semiconductor layers to form third gaps between the semiconductor layers of the second multilayer stack. The sacrificial semiconductor layers are removed to form the third gaps after forming second inner spacers in the second inner spacer notches. Method 10 further includes forming a first gate stack in the second gaps and a second gate stack in the third gaps at block 50. Processing associated with blocks 30-50 may be performed in various orders, including performing some processing of a first one of blocks 30-50, performing some processing of a second one of blocks 30-50, and then performing additional processing of the first one of blocks 30-50. Additional processing is contemplated by the present disclosure. Additional steps may be provided before, during, and after method 10, and some of the steps described may be moved, replaced, or eliminated for additional embodiments of method 10. The discussion that follows illustrates devices that may be fabricated according to method 10.

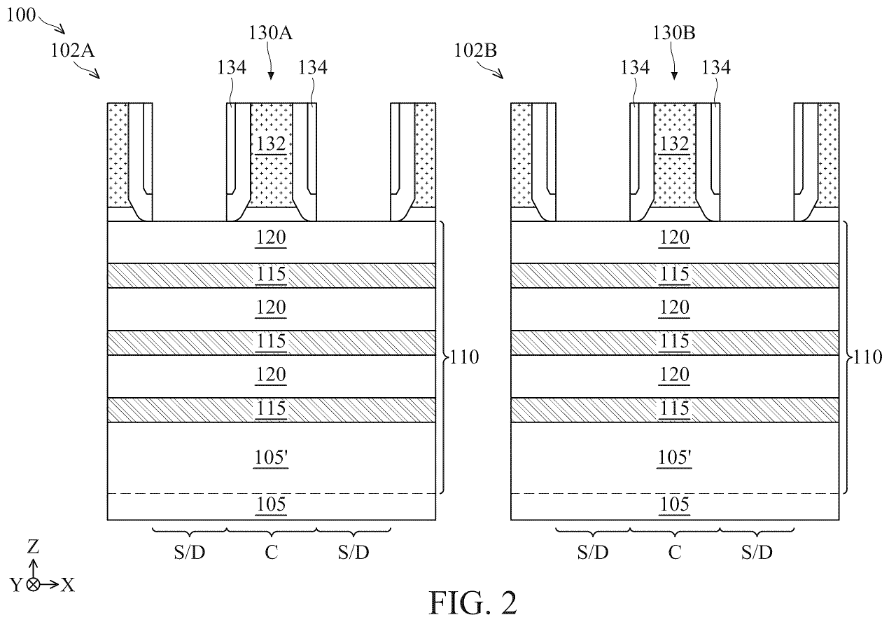

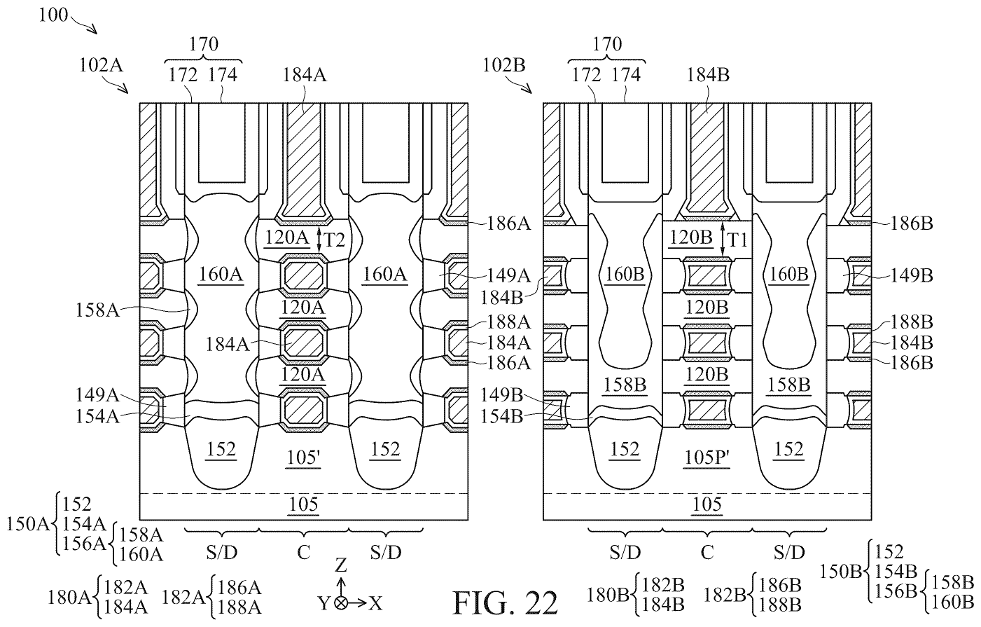

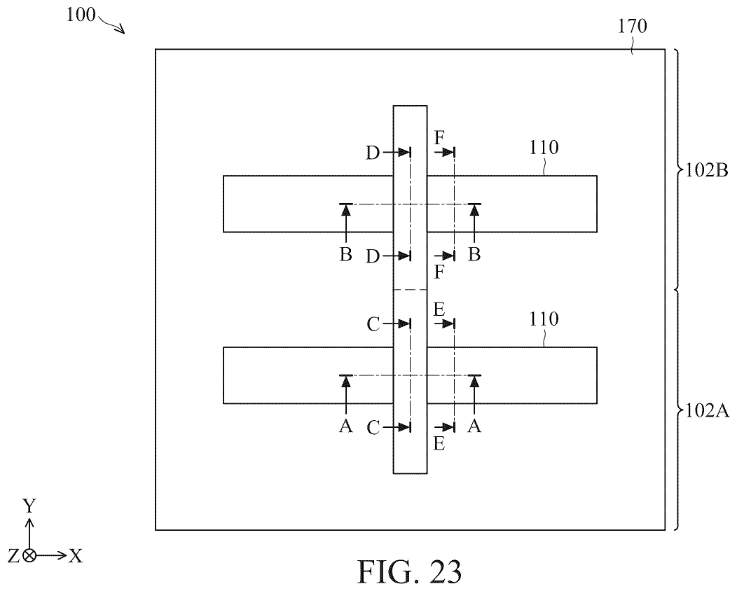

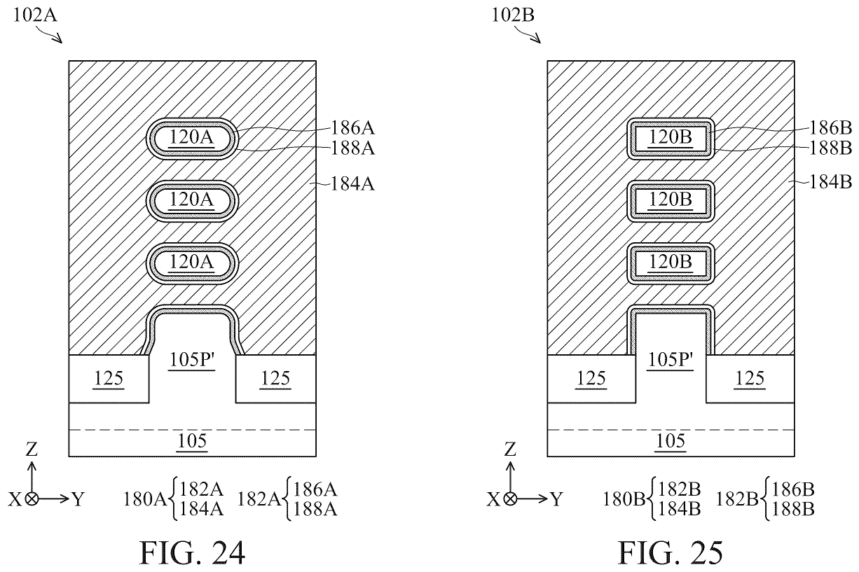

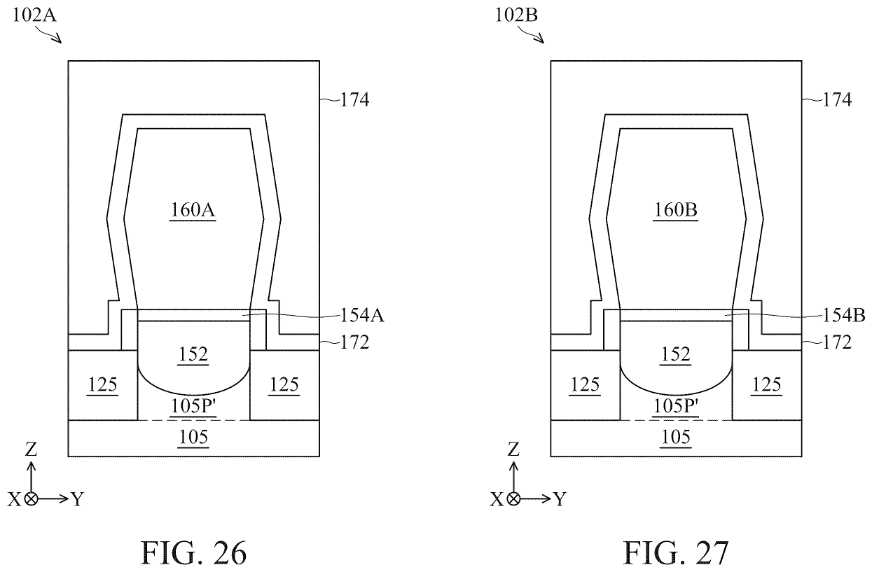

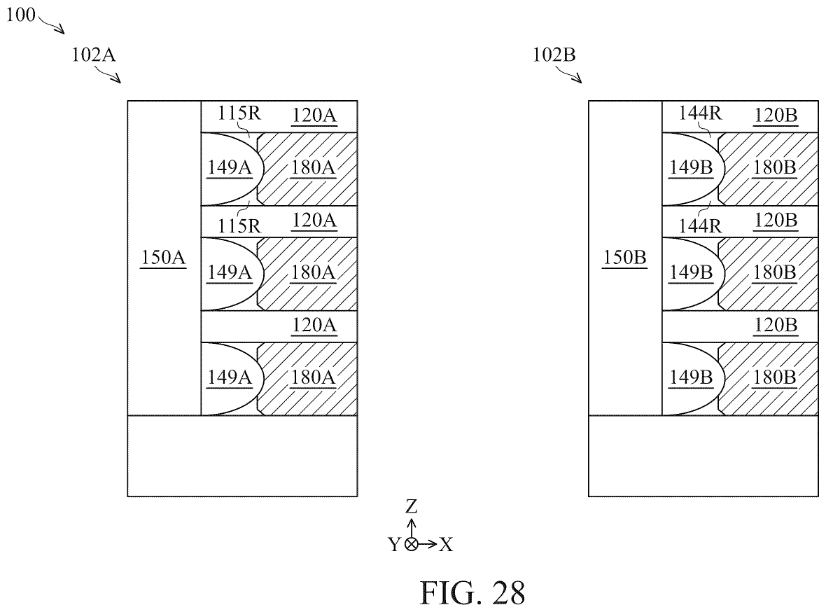

FIGS. 2-22 are cross-sectional views of a device 100, in portion or entirety, at various fabrication stages (such as those associated with method 10 in FIG. 1) according to various aspects of the present disclosure. FIG. 23 is a top view of device 100, in portion or entirety, of FIG. 22, where the cross-sectional views of FIG. 22 are taken along line A-A and line B-B of FIG. 23, according to various aspects of the present disclosure. FIG. 24 is a cross-sectional view of device 100, in portion or entirety, along line C-C of FIG. 23, according to various aspects of the present disclosure. FIG. 25 is a cross-sectional view of device 100, in portion or entirety, along line D-D of FIG. 23, according to various aspects of the present disclosure. FIG. 26 is a cross-sectional view of device 100, in portion or entirety, along line E-E of FIG. 23, according to various aspects of the present disclosure. FIG. 27 is a cross-sectional view of device 100, in portion or entirety, along line F-F of FIG. 23, according to various aspects of the present disclosure. FIG. 28 is a cross-sectional view of portions of device 100, in portion or entirety, of FIG. 22, according to various aspects of the present disclosure. FIGS. 2-28 are discussed concurrently herein for ease of description and understanding. FIGS. 2-28 have been simplified for the sake of clarity to better understand the inventive concepts of the present disclosure. Additional features may be added in device 100, and some of the features described below may be replaced, modified, or eliminated in other embodiments of device 100.

After undergoing processing associated with FIGS. 2-22, device 100 may include at least one GAA transistor (i.e., a transistor having a gate that at least partially surrounds a suspended channel(s) (for example, a nanowire(s), a nanosheet(s), a nanobar(s), or the like) that extends between source/drains). For example, device 100 may be processed to form a first transistor in a device region 102A and a second transistor in a device region 102B. In the depicted embodiment, device 100 is processed to form an n-type transistor in device region 102A and a p-type transistor in device region 102B. In such embodiments, device 100 may include a complementary metal-oxide semiconductor (CMOS) transistor. Device 100 may be included in a microprocessor, a memory, other IC device, or combinations thereof. In some embodiments, device 100 is a portion of an IC chip, a system on chip (SoC), or portion thereof, and device 100 may include various passive electronic devices and/or active electronic devices, such as resistors, capacitors, inductors, diodes, p-type field effect transistors (PFETs), n-type FETs (NFETs), metal-oxide-semiconductor FETs (MOSFETs), CMOS transistors, bipolar junction transistors (BJTs), laterally diffused MOS (LDMOS) transistors, high voltage transistors, high frequency transistors, other suitable components, or combinations thereof.

Referring to FIG. 2, fabrication of device 100 may include forming and/or receiving a device precursor, which may include a substrate 105, multilayer stacks 110 (each including, e.g., a mesa 105′, sacrificial semiconductor layers 115, and semiconductor layers 120), substrate isolation structures 125, gate structures 130A in device region 102A, and gate structures 130B in device region 102B. In the depicted embodiment, gate structures 130A and gate structures 130B include a respective dummy gate stack 132 and respective gate spacers 134.

Substrate 105 includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 105 is a silicon substrate. In some embodiments, substrate 105 is a semiconductor-on-insulator substrate, such as a silicon-on-insulator (SOI) substrate, a silicon germanium-on-insulator (SGOI) substrate, or a germanium-on-insulator (GOI) substrate. Substrate 105 (and mesas 105′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include p-type dopants and n-type dopants. The doped regions may be formed on and/or in substrate 105, for example, providing a p-well structure, an n-well structure, a dual-well structure, a raised structure, other suitable structure, or combinations thereof. In some embodiments, substrate 105 and/or mesas 105′, and semiconductor layers thereover, may include an n-well and/or a p-well. For example, mesas 105′ may include a p-well in device region 102A, such as where an n-type transistor is formed therein, and an n-well in device region 102B, such as where a p-type transistor is formed therein, or vice versa.

In some embodiments, multilayer stacks 110 are formed by depositing sacrificial semiconductor layers 115 and semiconductor layers 120 over substrate 105 and patterning sacrificial semiconductor layers 115, semiconductor layers 120, and substrate 105. Sacrificial semiconductor layers 115 and semiconductor layers 120 are stacked vertically (e.g., along the z-direction) in an interleaving and/or alternating configuration from a top of substrate 105. In some embodiments, the depositing includes epitaxially growing sacrificial semiconductor layers 115 and semiconductor layers 120 in the depicted interleaving/alternating configuration. For example, a first one of sacrificial semiconductor layers 115 is epitaxially grown on substrate 105, a first one of semiconductor layers 120 is epitaxially grown on the first one of sacrificial semiconductor layers 115, a second one of sacrificial semiconductor layers 115 is epitaxially grown on the first one of semiconductor layers 120, and so on until multilayer stacks 110 have a desired number of sacrificial semiconductor layers 115 and semiconductor layers 120. In such embodiments, sacrificial semiconductor layers 115 and semiconductor layers 120 may be referred to as epitaxial layers. In some embodiments, epitaxial growth of sacrificial semiconductor layers 115 and semiconductor layers 120 is achieved by a molecular beam epitaxy (MBE) process, a chemical vapor deposition (CVD) process, a metalorganic (MOCVD) process, other suitable epitaxial growth process, or combinations thereof.

A composition of sacrificial semiconductor layers 115 is different than a composition of semiconductor layers 120 to achieve etch selectivity. For example, sacrificial semiconductor layers 115 and semiconductor layers 120 include different materials, constituent atomic percentages, constituent weight percentages, other characteristics, or combinations thereof to achieve etch selectivity. In some embodiments, sacrificial semiconductor layers 115 include silicon germanium, semiconductor layers 120 include silicon, and an etch rate of semiconductor layers 120 is different than an etch rate of sacrificial semiconductor layers 115 to a given etchant. In some embodiments, sacrificial semiconductor layers 115 and semiconductor layers 120 include the same material but with different constituent atomic percentages. For example, sacrificial semiconductor layers 115 and semiconductor layers 120 may include silicon germanium, and sacrificial semiconductor layers 115 and semiconductor layers 120 may have different germanium atomic percentages to provide etch selectivity. Sacrificial semiconductor layers 115 and semiconductor layers 120 may include any combination of materials that provides desired etching selectivity, desired oxidation rate differences, desired performance characteristics (e.g., materials that maximize current flow), or combinations thereof.

Semiconductor layers 120 or portions thereof may form channels of transistors in device region 102A and transistors in device region 102B. In the depicted embodiment, multilayer stacks 110 include three sacrificial semiconductor layers 115 and three semiconductor layers 120. Multilayer stacks 110 thus include three semiconductor layer pairs disposed over substrate 105, each of which has a respective sacrificial semiconductor layer 115 and a respective semiconductor layer 120. After processing of multilayer stacks 110, this configuration may result in transistors having three channels. However, in some embodiments, multilayer stacks 110 include different numbers of semiconductor layers 120 depending, for example, on a number of channels desired for the transistors. For example, multilayer stacks 110 may include two to six semiconductor layer pairs, each of which has a respective sacrificial semiconductor layer 115 and a respective semiconductor layer 120.

After patterning, multilayer stacks 110 include a respective mesa 105′ (also referred to as a substrate extension, a substrate fin portion, a fin portion, an etched substrate portion, etc.) and a respective semiconductor layer stack portion (i.e., sacrificial semiconductor layers 115 and semiconductor layers 120). Multilayer stacks 110 may be referred to as a fin, a fin structure, a fin element, an active fin region, an active region, etc. Multilayer stacks 110 extend substantially along an x-direction, having a length along the x-direction, a width along a y-direction, and a height along a z-direction. In some embodiments, a lithography process and/or an etching process is performed to pattern sacrificial semiconductor layers 115, semiconductor layers 120, and substrate 105 to form multilayer stacks 110. In some embodiments, multilayer stacks 110 are formed by a multiple patterning process, such as a double patterning lithography (DPL) process (for example, a lithography-etch-lithography-etch (LELE) process, a self-aligned double patterning (SADP) process, a spacer-is-dielectric (SID) process, other double patterning process, or combinations thereof), a triple patterning process (for example, a lithography-etch-lithography-etch-lithography-etch (LELELE) process, a self-aligned triple patterning (SATP) process, other triple patterning process, or combinations thereof), other multiple patterning process (for example, self-aligned quadruple patterning (SAQP) process), or combinations thereof. In some embodiments, directed self-assembly (DSA) techniques are implemented. In some embodiments, multilayer stacks 110 are formed by a fin fabrication process.

Substrate isolation structures 125 (see FIGS. 24-27) may be formed adjacent to and around a lower portion of multilayer stacks 110 (e.g., mesas 105′ thereof), and multilayer stacks 110 may be separated from other multilayer stacks and/or other device regions by substrate isolation structures 125. Substrate isolation structures 125 may electrically isolate an active device region (e.g., multilayer stacks 110) from other device regions, such as other multilayer stacks. Substrate isolation structures 125 include silicon oxide, silicon nitride, silicon oxynitride, other suitable isolation material (including, silicon, oxygen, nitrogen, carbon, other suitable isolation constituent, or combinations thereof), or combinations thereof. Substrate isolation structures 125 may have a multilayer structure. For example, substrate isolation structures 125 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 125 may include a bulk dielectric over a doped liner, such as a boron silicate glass (BSG) liner and/or a phosphosilicate glass (PSG) liner. Dimensions and/or characteristics of substrate isolation structures 125 may be configured to provide shallow trench isolation (STI) structures, deep trench isolation (DTI) structures, local oxidation of silicon (LOCOS) structures, other suitable isolation structures, or combinations thereof.

Gate structures 130A and gate structures 130B may be formed over channel regions (C) of multilayer stacks 110 and between respective source/drain regions (S/D) of multilayer stacks 110. Dummy gate stacks 132 extend lengthwise along a direction different than (e.g., orthogonal to) the lengthwise direction of multilayer stacks 110. For example, dummy gate stacks 132 extend along the y-direction, having a length along the y-direction, a width along the x-direction, and a height along the z-direction. Dummy gate stacks 132 may extend substantially parallel to one another. In FIG. 2 (e.g., the X-Z plane), dummy gate stacks 132 are disposed on top of respective channel regions, and dummy gate stacks 132 are disposed between respective source/drain regions. In cross-sectional views along a Y-Z plane, dummy gate stacks 132 may wrap respective channel regions (e.g., be disposed over the top and sidewalls thereof), and dummy gate stacks 132 may be disposed over tops of substrate isolation structures 125.

Dummy gate stacks 132 may include a dummy gate dielectric and a dummy gate electrode. The dummy gate dielectric includes a dielectric material, such as silicon oxide. The dummy gate electrode includes a dummy gate material, such as polysilicon. Dummy gate stacks 132 may further include hard masks over the dummy gate electrodes. The hard masks may be configured to protect dummy gate stacks 132 during processing. For example, the hard masks may include any material that is resistant to an etching process, such as a source/drain etch, to protect dummy gate electrodes therefrom. In some embodiments, the hard masks have a multilayer structure, such as a first mask layer disposed over a second mask layer.

Gate spacers 134 are formed adjacent to and along sidewalls of dummy gate stacks 132. Gate spacers 134 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, gate spacers 134 have a multilayer structure, such as two or more dielectric layers having different compositions. In some embodiments, gate spacers 134 include more than one set of spacers, such as seal spacers, offset spacers, sacrificial spacers, dummy spacers, main spacers, or combinations thereof. In such embodiments, the various sets of spacers may have different compositions.

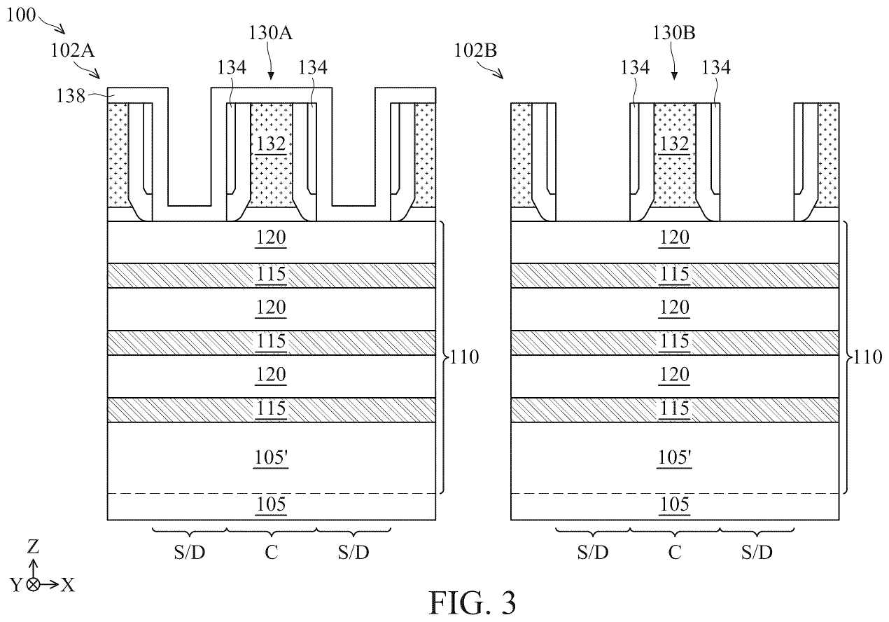

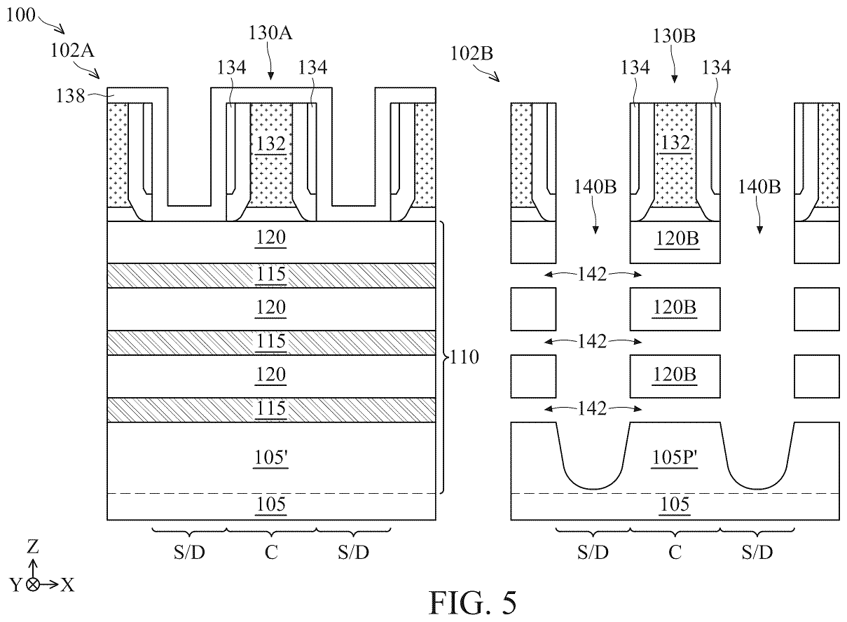

Referring to FIG. 3, a mask 138 is formed over device 100 that covers device region 102A (e.g., an n-type transistor region), but not device region 102B (e.g., a p-type transistor region). For example, mask 138 may have an opening therein that overlaps device region 102B. In some embodiments, mask 138 is formed by depositing a hard mask material over device region 102A and device region 102B and performing a patterning process to remove the hard mask material from device region 102B, thereby exposing device region 102B. The patterning process may include performing a lithography process to form a patterned resist layer that covers the hard mask material over device region 102A and exposes the hard mask material over device region 102B (e.g., the patterned resist layer has an opening therein that overlaps device region 102B) and performing an etching process to selectively remove the exposed hard mask material. A composition of mask 138 is different than compositions of sacrificial semiconductor layers 115, semiconductor layers 120, gate structures 130A, gate structures 130B, subsequently formed sacrificial oxide layer (see, e.g., FIGS. 5-7), or combinations thereof to enable selective removal/etching therebetween. In some embodiments, mask 138 includes metal and oxygen and/or nitrogen (e.g., mask 138 is a metal oxide mask and/or a metal nitride mask). For example, mask 138 may include aluminum and oxygen and/or nitrogen, and mask 138 may be an aluminum oxide mask, an aluminum oxynitride mask, an aluminum nitride mask, or combinations thereof. In some embodiments, mask 138 is a patterned resist layer.

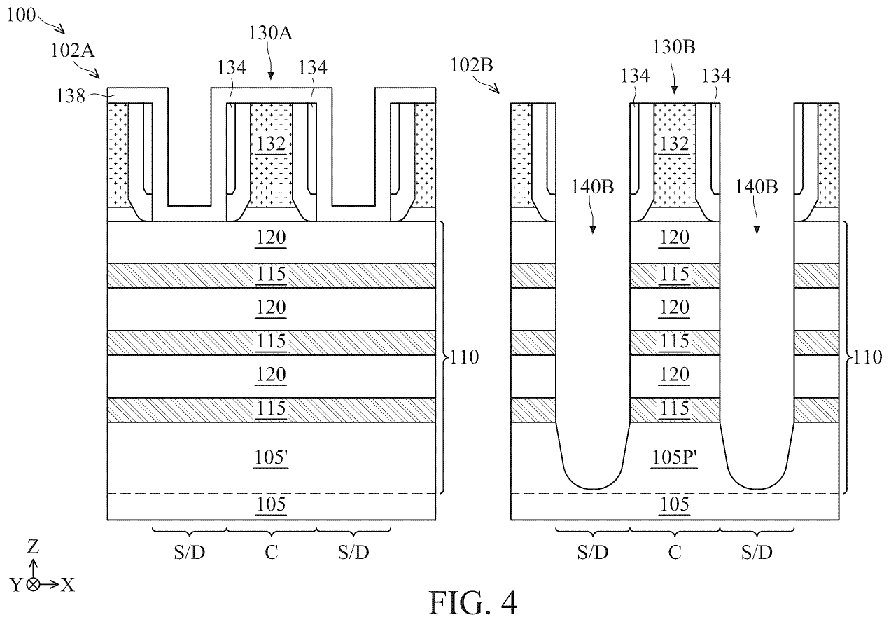

Referring to FIG. 4, a source/drain etch removes portions of multilayer stack 110 in device region 102B that are not covered by gate structures 130B, thereby forming source/drain recesses (trenches) 140B in device region 102B. For example, the source/drain etch removes semiconductor layers 120 and sacrificial semiconductor layers 115 in source/drain regions in device region 102B, thereby exposing mesa 105′ therein. The source/drain etch may further remove some, but not all, of mesa 105′ in source/drain regions in device region 102B, such that source/drain recesses 140B extend into but not through mesa 105′. After the source/drain etch, sacrificial semiconductor layers 115, semiconductor layers 120, and projecting portions formed from mesa 105′ (referred to hereafter as mesas 105P′) remain in channel regions, and source/drain recesses 140B expose sidewalls of sacrificial semiconductor layers 115, semiconductor layers 120, and mesas 105P′ remaining in channel regions. The source/drain etch is a dry etch, a wet etch, other suitable etch, or combinations thereof. In some embodiments, the source/drain etch is a multistep etch process, which may alternate etchants to remove sacrificial semiconductor layers 115 and semiconductor layers 120 separately and alternately. In some embodiments, source/drain etch parameters (e.g., etchant thereof) are tuned to selectively remove semiconductor materials (e.g., semiconductor layers 120, sacrificial semiconductor layers 115, and mesa 105′) with negligible (to no) removal of mask 138 and dielectric materials (e.g., dummy gate stacks 132, gate spacers 134, substrate isolation structures 125, etc.).

Referring to FIGS. 5-7, sacrificial semiconductor layers 115 are replaced with sacrificial oxide layers 144 in device region 102B. Referring to FIG. 5, an etching process selectively removes sacrificial semiconductor layers 115 exposed by source/drain recesses 140B, thereby forming gaps 142 in channel regions in device region 102B. The etching process may selectively remove sacrificial semiconductor layers 115 with respect to substrate 105, semiconductor layers 120, dummy gate stacks 132 (e.g., hard masks thereof), gate spacers 134, mask 138, or combinations thereof. In other words, the etching process removes sacrificial semiconductor layers 115 with negligible (to no) removal of substrate 105, semiconductor layers 120, dummy gate stacks 132 (e.g., hard masks thereof), gate spacers 134, mask 138, or combinations thereof. In some embodiments, an etchant is selected for the etching process that etches silicon germanium (e.g., sacrificial semiconductor layers 115) at a higher rate than silicon (e.g., semiconductor layers 120 and mesa 105′), dielectric materials (e.g., gate spacers 134 and hard masks of dummy gate stacks 132), and mask 138. The etching process is a dry etch, a wet etch, other suitable etch, or combinations thereof. In some embodiments, before the etching process, an oxidation process may be performed to convert sacrificial semiconductor layers 115 into semiconductor oxide layers (e.g., silicon germanium oxide layers). In such embodiments, the etching process removes semiconductor oxide layers to form gaps 142.

Semiconductor layers 120 remaining in channel regions are suspended over mesas 105P′ after removing sacrificial semiconductor layers 115. In the depicted embodiment, each channel region in device region 102B has three suspended semiconductor layers 120, which are referred to hereafter as channel layers 120B. Channel layers 120B are vertically stacked along the z-direction, and channel layers 120B may provide three channels through which current can flow between respective, subsequently formed source/drains. In some embodiments, after removing sacrificial semiconductor layers 115, an etching process may be performed to modify a profile of channel layers 120B to provide target dimensions and/or target shapes thereof. For example, the etching process may provide channel layers 120B with cylindrical-shaped profiles (e.g., nanowires), rectangular-shaped profiles (e.g., nanobars), sheet-shaped profiles (e.g., nanosheets (e.g., dimensions in the X-Y plane are sufficiently greater than dimensions in the X-Z plane and the Y-Z plane to form sheet-like structures)), or any other suitable shaped profile. In some embodiments, channel layers 120B have nanometer-sized dimensions and may be referred to as “nanostructures,” alone or collectively. In some embodiments, channel layers 120B have sub-nanometer dimensions and/or other suitable dimensions.

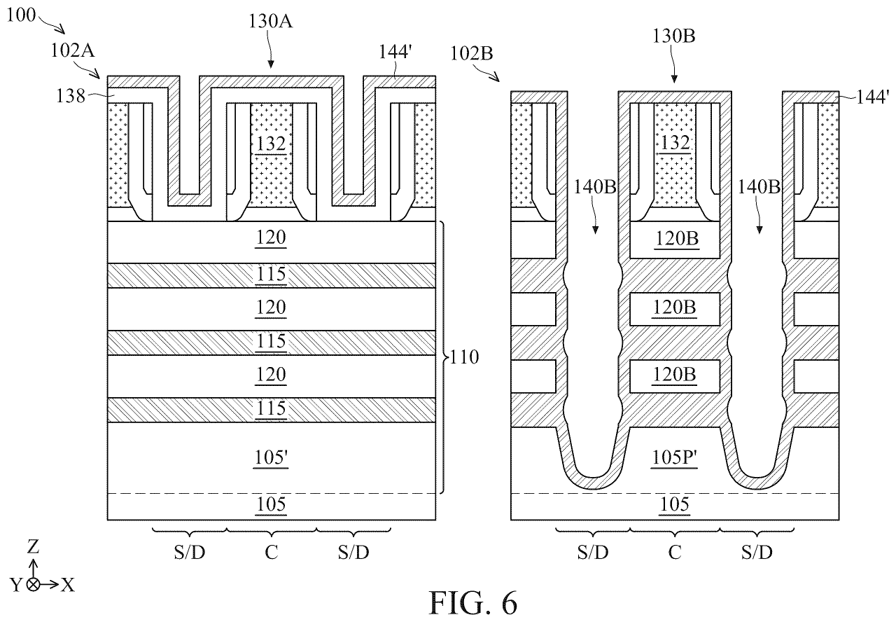

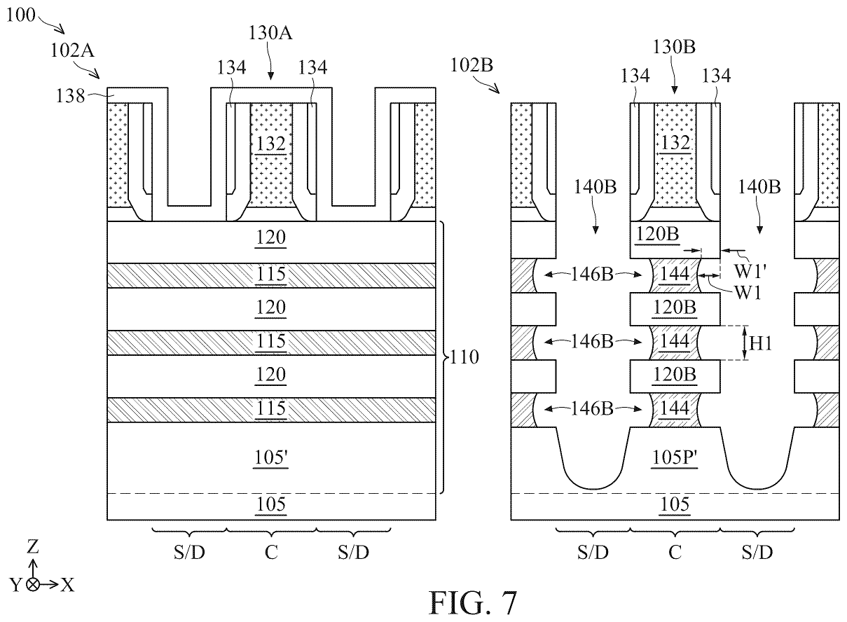

Referring to FIG. 6 and FIG. 7, sacrificial oxide layers 144 are formed in gaps 142. Sacrificial oxide layers 144 include oxygen and silicon, carbon, nitrogen, other suitable constituent, or combinations thereof. For example, sacrificial oxide layers 144 include oxygen and silicon, and sacrificial oxide layers 144 are silicon oxide layers. In some embodiments, sacrificial oxide layers 144 are formed by depositing an oxide layer 144′ over device 100 (e.g., over device region 102A and device region 102B) (e.g., FIG. 6) and etching oxide layer 144′, such that oxide layer 144′ is removed from source/drain regions, but not channel regions, of device 200. Referring to FIG. 6, as-deposited oxide layer 144′ fills gaps 142, partially fills source/drain recesses 140B, and lines source/drain recesses 140B. As-deposited oxide layer 144′ may further be disposed over gate structures 130B, such as along tops and sidewalls thereof, and over mask 138 in device region 102A. In the depicted embodiment, oxide layer 144′ is formed by flowable chemical vapor deposition (FCVD). In some embodiments oxide layer 144′ is formed by atomic layer deposition (ALD), plasma enhanced chemical vapor deposition (PECVD), other deposition process, or combinations thereof. In some embodiments, sacrificial oxide layers 144 have multilayer structures, such as a first oxide layer and a second oxide layer. The first oxide layer and the second oxide layer may be formed of a same material (e.g., silicon oxide), but formed by different deposition processes. For example, the first oxide layer may be formed over device region 102A and device region 102B by ALD, and the second oxide layer may be formed over the first oxide layer by FCVD. In some embodiments, the first oxide layer and the second oxide layer are formed of different oxide materials, which may be deposited by a same type of deposition process or different types of deposition processes.

Referring to FIG. 7, an etching process removes exposed portions of oxide layer 144′ (e.g., those not filling gaps 142). For example, the etching process removes portions of oxide layer 144′ in device region 102A, such as portions disposed on mask 138, and portions of oxide layer 144′ in device region 102B, such as portions disposed on sidewalls of channel layers 120B, sidewalls of mesas 105P′, surfaces of mesa 105′ that form bottoms of source/drain recesses 140B, sidewalls of gate spacers 134, tops of gate spacers 134, and tops of dummy gate stacks 132. Remainders of oxide layer 144′ provide sacrificial oxide layers 144 in the channel regions. The etching process selectively removes oxide layer 144′ with respect to substrate 105, channel layers 120B, dummy gate stacks 132 (e.g., hard masks thereof), gate spacers 134, mask 138, or combinations thereof. In other words, the etching process removes oxide layer 144′ with negligible (to no) removal of substrate 105, channel layers 120B, dummy gate stacks 132 (e.g., hard masks thereof), gate spacers 134, mask 138, or combinations thereof. In some embodiments, an etchant is selected that etches an oxide material (e.g., oxide layer 144′) at a higher rate than silicon (e.g., channel layers 120B and mesa 105′), dielectric materials different than the oxide material (e.g., gate spacers 134 and dummy gate stacks 132), and mask 138. The etching process is a dry etch, a wet etch, other suitable etch, or combinations thereof.

In some embodiments, the etching process (e.g., an anisotropic etch) further laterally recesses sacrificial oxide layers 144 to form notches 146B under gate structures 130B (e.g., under gate spacers 134 thereof). For example, the etching process may laterally etch (e.g., along the x-direction and/or the y-direction) sacrificial oxide layers 144 to reduce their lengths along the x-direction, such that lengths of sacrificial oxide layers 144 are less than lengths of channel layers 120B. Sacrificial oxide layers 144 may be completely removed from ends of channel layers 120B, thereby exposing tops and bottoms of ends of channel layers 120B. In some embodiments, notches 146B laterally extend (e.g., along the x-direction) under dummy gate stacks 132. Notches 146B (also referred to as inner spacer recesses) have widths along the x-direction between sidewalls of channel layers 120B and recessed sidewalls of sacrificial oxide layers 144, and notches 146B have heights along the z-direction between adjacent channel layers 120B and between bottom channel layers 120B and mesas 105P′. In the depicted embodiment, oxide layers 144 have concave sidewalls, resulting in notches 146B having widths that vary along heights thereof. For example, notches 146B may include central portions having widths W1 and ends having widths W1′. In such embodiments, widths of notches 146B may increase from width W1′ (e.g., a minimum notch width) proximate a respective upper channel layer 120B to width W1 (e.g., a maximum notch width) at a distance below the respective upper channel layer 120B and then decrease from width W1 to width W1′ proximate a respective lower channel layer 120B (or mesa 105P′). In some embodiments, width W1 is about 1 nm to about 8 nm. In some embodiments, a ratio of width W1 to width W1′ is greater than about 1 and less than about 3 (i.e., 1<W1:W1′<3). In some embodiments, height H1 is greater than about 3 nm.

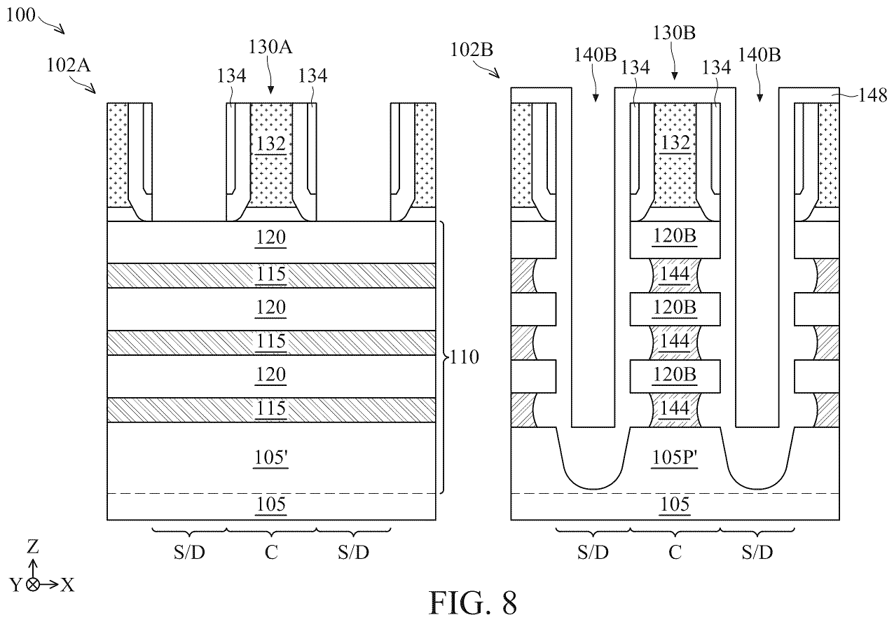

Referring to FIG. 8, mask 138 is removed from device region 102B by any suitable process (e.g., an etching process, a resist stripping process, other suitable process, or combinations thereof), and a mask 148 is formed over device 100 that covers device region 102B (e.g., a p-type transistor region), but not device region 102A (e.g., an n-type transistor region). For example, mask 148 may have an opening therein that overlaps device region 102A. In some embodiments, mask 148 is formed by depositing a hard mask material over device region 102A and device region 102B and performing a patterning process to remove the hard mask material from device region 102A, thereby exposing device region 102A. The patterning process may include performing a lithography process to form a patterned resist layer that covers the hard mask material over device region 102B and exposes the hard mask material over device region 102A (e.g., the patterned resist layer has an opening therein that overlaps device region 102A) and performing an etching process to selectively remove the exposed hard mask material. Mask 148 may fill notches 146B, such as depicted. A composition of mask 148 is different than compositions of sacrificial semiconductor layers 115, semiconductor layers 120, channel layers 120B, gate structures 130A, gate structures 130B, sacrificial oxide layers 144, or combinations thereof to enable selective removal/etching therebetween. In some embodiments, mask 148 includes metal and oxygen and/or nitrogen (e.g., mask 148 is a metal oxide mask and/or a metal nitride mask). For example, mask 148 may include aluminum and oxygen and/or nitrogen, and mask 148 may be an aluminum oxide mask, an aluminum oxynitride mask, an aluminum nitride mask, or combinations thereof. In some embodiments, mask 148 is a patterned resist layer.

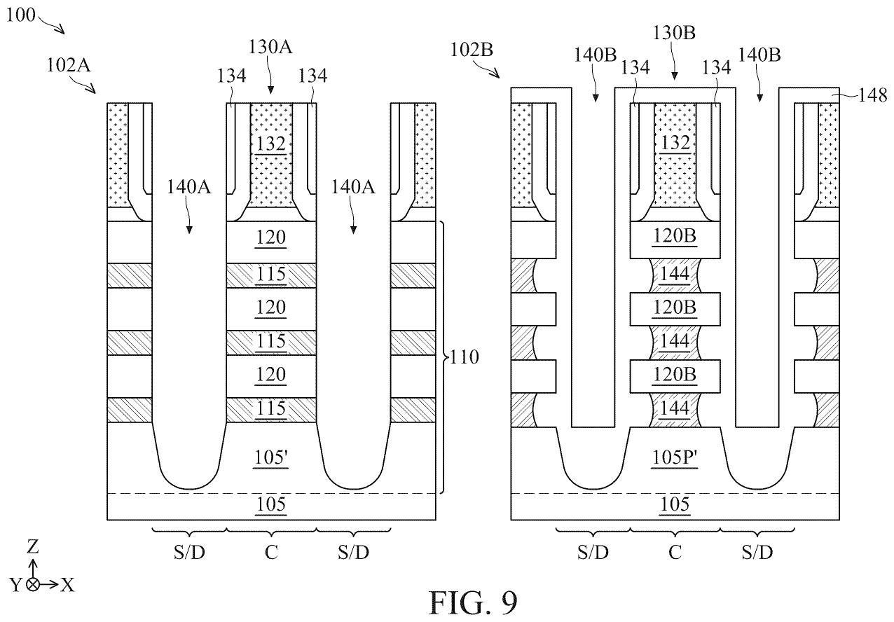

Referring to FIG. 9, a source/drain etch removes portions of multilayer stack 110 in device region 102A that are not covered by gate structures 130A, thereby forming source/drain recesses (trenches) 140A in device region 102A. For example, the source/drain etch removes semiconductor layers 120 and sacrificial semiconductor layers 115 in source/drain regions in device region 102A, thereby exposing mesa 105′ therein. The source/drain etch may further remove some, but not all, of mesa 105′ in source/drain regions in device region 102A, such that source/drain recesses 140A extend into but not through mesa 105′. After the source/drain etch, sacrificial semiconductor layers 115, semiconductor layers 120, and projecting portions formed from mesa 105′ (referred to hereafter as mesas 105P′) remain in channel regions, and source/drain recesses 140A expose sidewalls of sacrificial semiconductor layers 115, semiconductor layers 120, and mesas 105P′ remaining in channel regions. The source/drain etch is a dry etch, a wet etch, other suitable etch, or combinations thereof. In some embodiments, the source/drain etch is a multistep etch process, which may alternate etchants to remove sacrificial semiconductor layers 115 and semiconductor layers 120 separately and alternately. In some embodiments, source/drain etch parameters (e.g., etchant thereof) are tuned to selectively remove semiconductor materials (e.g., semiconductor layers 120, sacrificial semiconductor layers 115, and mesa 105′) with negligible (to no) removal of mask 148 and dielectric materials (e.g., dummy gate stacks 132, gate spacers 134, substrate isolation structures 125, etc.).

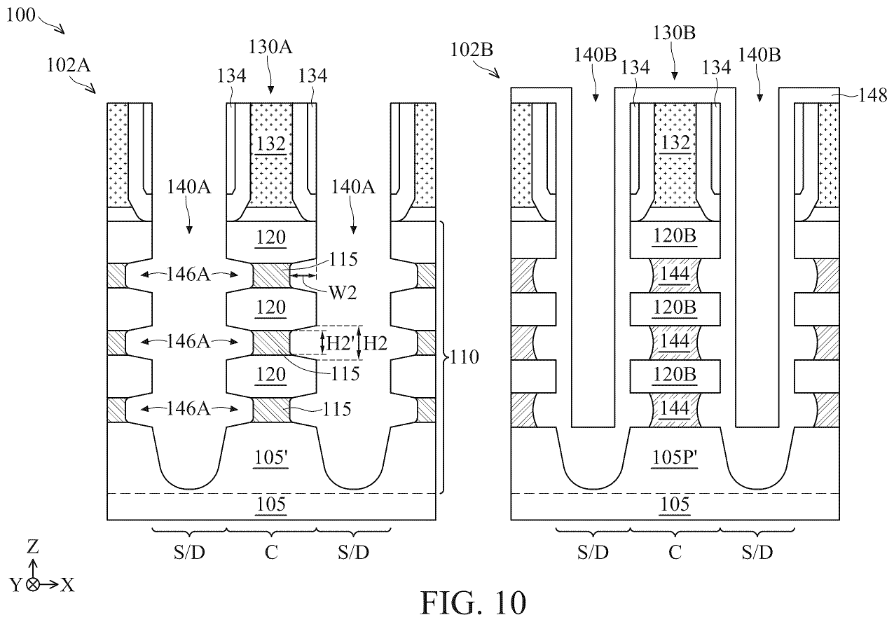

Referring to FIG. 10, an etching process (e.g., an anisotropic etch) laterally recesses sacrificial semiconductor layers 115 to form notches 146A under gate structures 130A (e.g., under gate spacers 134 thereof). For example, the etching process may laterally etch (e.g., along the x-direction and/or the y-direction) sacrificial semiconductor layers 115 to reduce their lengths along the x-direction, such that lengths of sacrificial semiconductor layers 115 are less than lengths of semiconductor layers 120. Sacrificial semiconductor layers 115 may be completely removed from ends of semiconductor layers 120, thereby exposing tops and bottoms of ends of semiconductor layers 120. In some embodiments, notches 146A laterally extend (e.g., along the x-direction) under dummy gate stacks 132. Notches 146A have widths along the x-direction between sidewalls of semiconductor layers 120 and recessed sidewalls of sacrificial semiconductor layers 115, and notches 146A have heights along the z-direction between adjacent semiconductor layers 120 and between bottom semiconductor layers 120 and mesas 105P′.

Because etch selectivity of sacrificial semiconductor layers 115 and semiconductor layers 120 is different than (e.g., less than) etch selectivity of sacrificial oxide layers 144 and semiconductor layers 120, notches 146A and notches 146B may have different configurations. For example, because an etchant for etching sacrificial oxide layers 144 with respect to semiconductor layers 120 (i.e., an etchant for removing oxide relative to silicon) may provide better etch selectivity than an etchant for etching sacrificial semiconductor layers 115 with respect to semiconductor layers 120 (i.e., an etchant for removing silicon germanium relative to silicon), channel layers 120B may not be etched when forming notches 146B, thereby providing notches 146B with substantially uniform heights (e.g., height H1) along their widths, while semiconductor layers 120 may be slightly etched/thinned when forming notches 146A, thereby providing notches 146A with varying heights along their widths. For example, notches 146A may have heights that decrease from a height H2 (e.g., a maximum height of notches 146A between ends of semiconductor layers 120, which have been thinned by the etching process) to a height H2′ (e.g., a minimum height of notches 146A). In some embodiments, a ratio of height H2 to height H2′ is greater than about 1 and less than about 1.5 (i.e., 1<H2:H2′<1.5). In some embodiments, height H2 is greater than about 3 nm. In some embodiments, height H2′ is greater than about 3 nm. Further, because the etch selectivity differences may result in more aggressive etching of sacrificial oxide layers 144 relative to semiconductor layers 120 than sacrificial semiconductor layers 115 relative to semiconductor layers 120, recessed, etched sacrificial semiconductor layers 115 and recessed, etched sacrificial oxide layers 144 have different sidewall profiles, thereby providing notches 146A and notches 146B with different profiles. For example, sacrificial semiconductor layers 115 may have substantially straight sidewalls, such as depicted, resulting in notches 146A having substantially uniform widths, such as a width W2, along their heights. In some embodiments, width W2 is about 1 nm to about 8 nm.

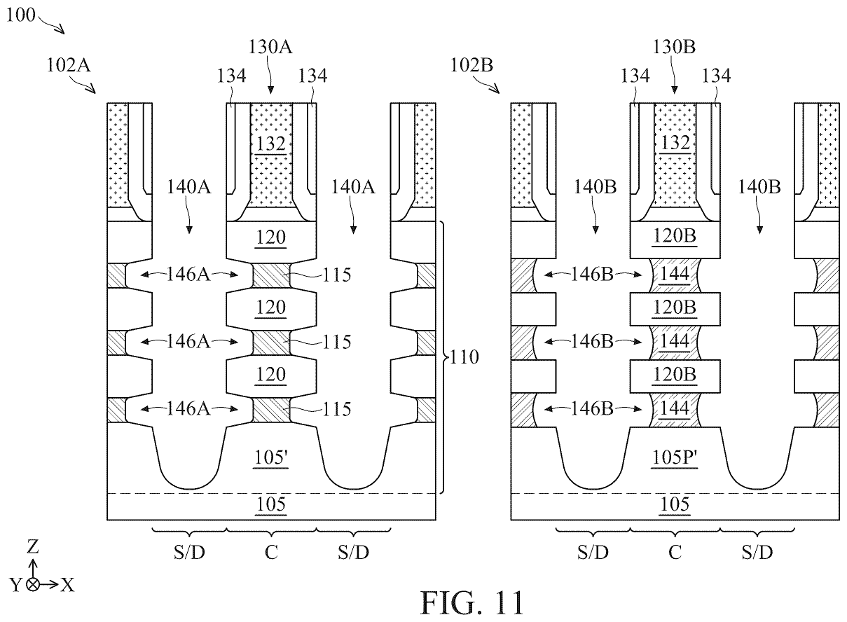

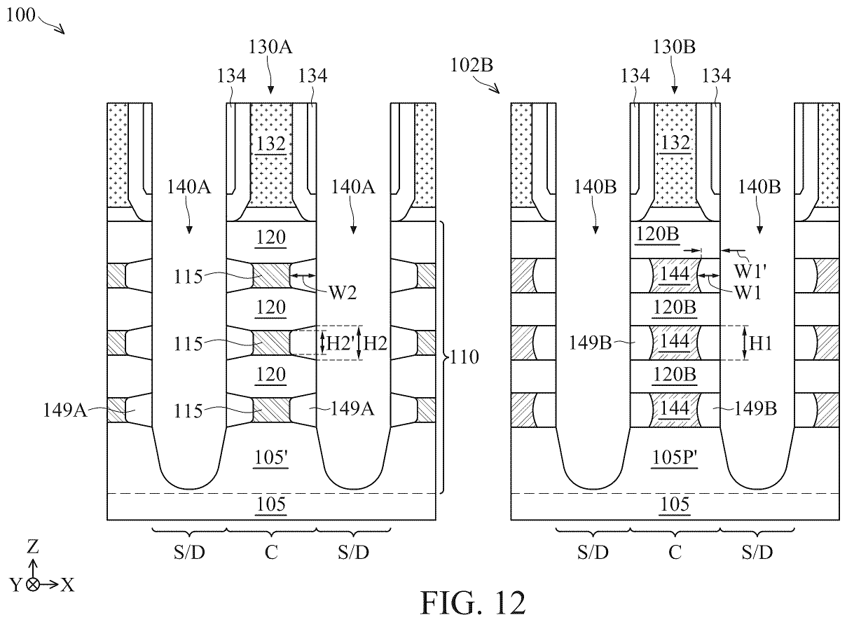

Referring to FIG. 11, mask 148 is removed from device region 102A by any suitable process, such as an etching process, a resist stripping process, other suitable process, or combinations thereof. Referring to FIG. 12, inner spacers 149A are formed in notches 146A in device region 102A, and inner spacers 149B are formed in notches 146B in device region 102B. Inner spacers 149A are disposed under gate spacers 134 along sidewalls of sacrificial semiconductor layers 115, and inner spacers 149B are disposed under gate spacers 134 along sidewalls of sacrificial oxide layers 144. Inner spacers 149A and inner spacers 149B may replace ends of sacrificial semiconductor layers 115 and sacrificial oxide layers 144, respectively. In the depicted embodiment, remainders of sacrificial semiconductor layers 115 are disposed between respective inner spacers 149A, and remainders of sacrificial oxide layers 144 are disposed between respective inner spacers 149B. Further, inner spacers 149A are disposed between ends of respective semiconductor layers 120, bottom inner spacers 149A are disposed between ends of respective bottom semiconductor layers 120 and respective mesas 105P′, inner spacers 149B are disposed between ends of respective channel layers 120B, and bottom inner spacers 149B are disposed between ends of respective bottom channel layers 120B and respective mesas 105P′. Because notches 146A and notches 146B have different configurations (e.g., different dimensions and/or different shapes), inner spacers 149A and inner spacers 149B may have different configurations. For example, inner spacers 149A may have substantially uniform widths (e.g., width W2) and heights that vary along their widths (e.g., from height H2 to height H2′), and inner spacers 149B may have substantially uniform heights (e.g., height H1) and widths that vary along their heights (e.g., from width W1 to width W1′).

Inner spacers 149A and inner spacers 149B may be formed at the same time, for example, by an inner spacer deposition and an inner spacer etch. The inner spacer deposition forms an inner spacer layer over device 100 that at least partially fills notches 146A and notches 146B. In some embodiments, a single deposition process is performed to form an inner spacer layer that fills notches 146A and notches 146B. In some embodiments, inner spacers 149A and inner spacers 149B have multilayer structures, and the inner spacer deposition includes more than one deposition process to form a multilayer inner spacer layer, such as a first deposition process to form a first inner spacer sublayer and a second deposition process to form a second inner spacer sublayer. The first inner spacer sublayer partially fills notches 146A and notches 146B, and the second inner spacer sublayer may partially or completely fill notches 146A and notches 146B. A composition and/or a material of the first inner spacer sublayer is the same or different than a composition and/or a material of the second inner spacer sublayer.

The inner spacer etch may selectively etch the inner spacer layer with negligible (to no) etching of semiconductor layers 120, channel layers 120B, mesas 105P′, dummy gate stacks 132 (e.g., hard masks thereof), gate spacers 134, substrate isolation structures 125, or combinations thereof. Remainders of the inner spacer layer provide inner spacers 149A and inner spacers 149B, such as depicted. To achieve desired etching selectivity, the inner spacer layer (and thus inner spacers 149A and inner spacers 149B) have a composition different than compositions of semiconductor layers 120, channel layers 120B, mesas 105P′, dummy gate stacks 132, gate spacers 134, substrate isolation structures 125, or combinations thereof. In some embodiments, the inner spacer layer includes a dielectric material that includes silicon, oxygen, carbon, nitrogen, other suitable dielectric constituent, or combinations thereof. For example, the inner spacer layer may be a silicon carbide layer, a silicon carbonitride layer, a silicon oxycarbonitride layer, a silicon oxycarbide layer, or combinations thereof. The inner spacer etch is a dry etch, a wet etch, other suitable etch, or combinations thereof. In some embodiments, parameters of the inner spacer deposition and/or the inner spacer etch are configured and/or tuned to provide inner spacers 149A and inner spacers 149B with air gaps.

In some embodiments, inner spacers 149A and inner spacers 149B are formed separately by a respective inner spacer deposition and etch. In such embodiments, device region 102A may be masked while forming inner spacers 149B, and device region 102B may be masked while forming inner spacers 149A. For example, mask 138 may remain over device region 102A while forming inner spacers 149B in notches 146B, and mask 148 may remain over device region 102B while forming inner spacers 149A in notches 146A. In such example, mask 148 may be formed over inner spacers 149B, instead of filling notches 146B. In some embodiments, when formed separately, inner spacers 149A and inner spacers 149B are formed of the same materials and/or include the same inner spacer sublayers. In some embodiments, when formed separately, inner spacers 149A and inner spacers 149B are formed of different materials and/or include different inner spacers sublayers or configurations.

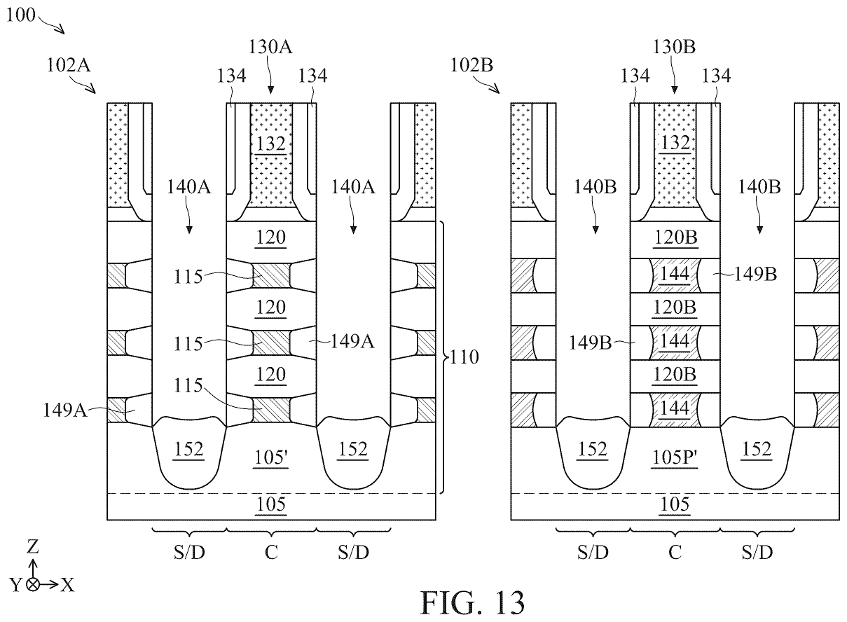

Referring to FIGS. 13-15, source/drain structures 150A are formed in source/drain recesses 140A, and source/drain structures 150B are formed in source/drain recesses 140B. Source/drain structures 150A and source/drain structures 150B may be referred to collectively as source/drain structures 150 herein. Source/drain structures 150A may include a respective undoped semiconductor layer 152, a respective insulator layer 154A, and a respective doped semiconductor layer 156A. In some embodiments, doped semiconductor layers 156A have a multilayer structure, such as a doped semiconductor layer 158A and a doped semiconductor layer 160A. Source/drain structures 150B may include a respective undoped semiconductor layer 152, a respective insulator layer 154A, and a respective doped semiconductor layer 156B. In some embodiments, doped semiconductor layers 156B have a multilayer structure, such as a doped semiconductor layer 158B and a doped semiconductor layer 160B. In the depicted embodiment, where device region 102A is an n-type transistor region and device region 102B is a p-type transistor region, source/drain structures 150A form source/drains of n-type transistors, and source/drain structures 150B form source/drains of p-type transistors. In such embodiments, source/drain structures 150A may include semiconductor material(s) doped with n-type dopant (e.g., carbon, phosphorous, arsenic, antimony, other n-type dopant, or combinations thereof), and source/drain structures 150B may include semiconductor material(s) doped with p-type dopant (e.g., boron, gallium, other p-type dopant, or combinations thereof). As used herein, source/drain, source/drain region, source/drain structure, source/drain feature, epitaxial source/drain, epitaxial source/drain feature, etc. may refer to a source of device 100, a drain of device 100, or a source and/or a drain of multiple devices (including device 100).

Referring again to FIG. 13, undoped semiconductor layers 152 may be formed in source/drain recesses 140A, such as in bottoms thereof, and source/drain recesses 140B, such as in bottoms thereof. In the depicted embodiment, undoped semiconductor layers 152 are formed simultaneously in device region 102A and device region 102B. In some embodiments, undoped semiconductor layers 152 are formed in device region 102A before or after forming undoped semiconductor layers 152 in device region 102B. Undoped semiconductor layers 152 are dopant-free (i.e., substantially free of n-type dopants and p-type dopants). For example, no intentional doping is performed when forming undoped semiconductor layers 152. Undoped semiconductor layers 152 may provide high resistance paths at bottoms of source/drains, thereby suppressing leakage current into substrate 105/mesas 105P′. Undoped semiconductor layers 152 include silicon, germanium, silicon germanium, other suitable semiconductor materials, or combinations thereof. In some embodiments, undoped semiconductor layers 152 are dopant-free silicon layers or dopant-free silicon germanium layers. In some embodiments, semiconductor materials having dopant concentrations less than about 5×10¹⁸ cm⁻³ (e.g., about 1×10¹⁸ cm⁻³ to about 5×10¹⁸ cm⁻³) are considered undoped and/or unintentionally doped (UID).

Undoped semiconductor layers 152 may be deposited on and/or grown from substrate 105, mesa 105′, mesas 105P′, or combinations thereof. In some embodiments, undoped semiconductor layers 152 are formed by a selective epitaxial growth (SEG) process, which may selectively deposit/grow semiconductor material (e.g., silicon) on/from exposed semiconductor surfaces. Undoped semiconductor layers 152 may thus be referred to as undoped epitaxial layers. The SEG process may use chemical vapor deposition (CVD) techniques (e.g., vapor-phase epitaxy (VPE), ultra-high vacuum CVD (UHV-CVD), low pressure CVD (LPCVD), plasma-enhanced CVD (PECVD), or the like), molecular beam epitaxy, other suitable epitaxial growth process, or combinations thereof. In some embodiments, undoped semiconductor layers 152 are formed by a bottom-up deposition process, such that semiconductor material is deposited on mesas 105P′, mesa 105′, and/or substrate 105 (i.e., in bottoms of source/drain recesses 140A and source/drain recesses 140B) with minimal (to no) deposition of semiconductor material on semiconductor layers 120 and channel layers 120B. In some embodiments, an etching process may be performed after the bottom-up deposition process to remove any semiconductor material that may have formed on semiconductor layers 120 and/or channel layers 120B. The post-deposition etch may be a dry etch, a wet etch, other suitable etch, or combinations thereof.

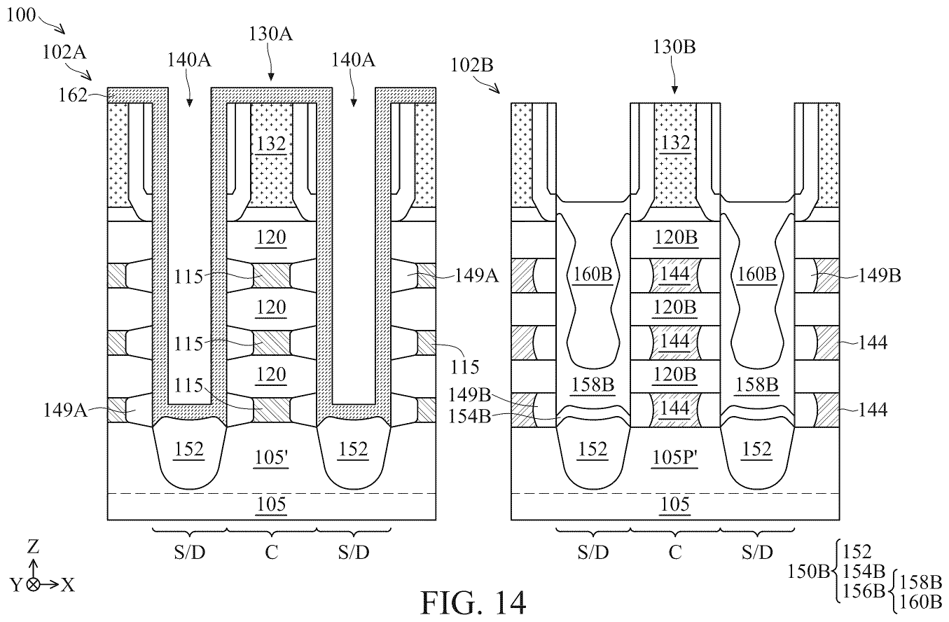

Referring to FIG. 14, fabrication of device 100 may include forming a mask 162 that covers device region 102A (e.g., an n-type transistor region), but not device region 102B (e.g., a p-type transistor region), and forming additional layers of source/drain structures 150B in device region 102B. For example, mask 162 has an opening therein that overlaps device region 102B. Mask 162 may be formed in a manner similar to other masks described herein, such as mask 138 and/or mask 148. A composition of mask 162 is different than compositions of source/drain structures 150A (e.g., undoped semiconductor layers 152 thereof), source/drain structures 150B (e.g., doped semiconductor layers 160B thereof), semiconductor layers 120, gate structures 130A, gate structures 130B, inner spacers 149A, or combinations thereof to enable selective removal/etching therebetween. In some embodiments, mask 162 includes metal and oxygen and/or nitrogen (e.g., mask 162 is a metal oxide mask and/or a metal nitride mask). For example, mask 162 may include aluminum and oxygen and/or nitrogen, and mask 162 may be an aluminum oxide mask, an aluminum oxynitride mask, an aluminum nitride mask, or combinations thereof. In some embodiments, mask 162 is a patterned resist layer.

Insulator layers 154A may be formed in source/drain recesses 140B over undoped semiconductor layers 152 while device region 102A is covered by mask 162. Insulator layers 154A partially fill source/drain recesses 140B, and insulator layers 154A may be disposed on bottommost inner spacers 149B and/or mesas 105P′. Insulator layers 154A include an electrically insulating material, such as a dielectric material, that may reduce unwanted leakage current, such as current that may undesirably flow between doped semiconductor layers 156B through mesas 105P′. In some embodiments, insulator layers 154A include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. In some embodiments, insulator layers 154A include a metal-comprising dielectric material, such as a metal oxide material and/or a metal nitride material. In some embodiments, insulator layers 154A include a doped semiconductor material that includes an opposite type of dopant than doped semiconductor layers 156B. For example, in the depicted embodiment, where doped semiconductor layers 156B are portions of source/drains of p-type transistors (e.g., p-type doped semiconductor layers), insulator layers 154A may include an n-type doped semiconductor material, such as phosphorous-doped silicon.

Insulator layers 154A may be formed by depositing an insulator material over device 100 and etching the insulator material, such that remainders of the insulator material fill bottoms of source/drain recesses 140B. The as-deposited insulator material may be disposed on tops of gate structures 130B (e.g., tops of gate spacers 134 and dummy gate stacks 132), sidewalls of gate structures 130B (e.g., of gate spacers 134), sidewalls of channel layers 120B, sidewalls of inner spacers 149B, sidewalls of mesas 105P′, and tops of mesa 105′ in source/drain regions. In some embodiments, as a result of properties of a deposition process (e.g., physical vapor deposition (PVD)), a thickness of the insulator material over horizontally oriented surfaces (e.g., tops of undoped semiconductor layers 152 in source/drain regions and tops of gate structures 130B) may be greater than a thickness of the insulator material over vertically oriented surfaces (e.g., sidewalls of gate structures 130B, sidewalls of channel layers 120B, and sidewalls of inner spacers 149B). Parameters of the etching may thus be tuned to remove vertically oriented portions of the insulator material, such as that on sidewalls of gate structures 130B, sidewalls of channel layers 120B, and sidewalls of inner spacers 149B. In such embodiments, as a result of etch loading effects, the etching may also remove horizontally oriented portions of the insulator material on top of gate structures 130B, but not (or minimally) horizontally oriented portions and/or vertically oriented portions of the insulator material in bottoms of source/drain recesses 140B, such as that disposed on undoped semiconductor layers 152 (i.e., the etching process may thin but not substantially remove such portions). In some embodiments, the as-deposited insulator material fills source/drain recesses 140B and the etching recesses the insulator material at least to bottom sacrificial oxide layers 144 and/or bottom inner spacers 149B. The etching may be a dry etch, a wet etch, other suitable etch, or combinations thereof.

Doped semiconductor layers 156B may also be formed in source/drain recesses 140B over insulator layers 154A and/or undoped semiconductor layers 152 while device region 102A is covered by mask 162. Doped semiconductor layers 156B fill remainders of source/drain recesses 140B, and doped semiconductor layers 156B are coupled to edges/ends of channel layers 120B. In the depicted embodiment, doped semiconductor layers 156B include doped semiconductor layers 158B and doped semiconductor layers 160B. Doped semiconductor layers 158B may be formed over channel layers 120B and partially fill source/drain recesses 140B, and doped semiconductor layers 160B may be formed over doped semiconductor layers 158B and/or insulator layers 154A and fill remainders of source/drain recesses 140B. Doped semiconductor layers 158B are between channel layers 120B and doped semiconductor layers 160B, and insulator layers 154A are between doped semiconductor layers 158B and undoped epitaxial layers 152. In the depicted embodiment, doped semiconductor layers 158B wrap doped semiconductor layers 160B, and doped semiconductor layers 158B are further between inner spacers 149B and doped semiconductor layers 160B. In some embodiments, doped semiconductor layers 158B is formed of discrete, separate portions, and each portion may be between a respective channel layer 120B and respective doped semiconductor layer 160B.

Doped semiconductor layers 158B and doped semiconductor layers 160B include silicon, germanium, silicon germanium, other suitable semiconductor materials, or combinations thereof. In some embodiments, doped semiconductor layers 158B and doped semiconductor layers 160B include the same semiconductor material with different constituent concentrations. For example, doped semiconductor layers 158B and doped semiconductor layers 160B may include silicon germanium and p-type dopant (e.g., boron and/or gallium), but different germanium concentrations and/or different p-type dopant concentrations. In some embodiments, doped semiconductor layers 158B have a smaller germanium concentration (e.g., Ge %) and/or a smaller p-type dopant concentration (e.g., B %) than doped semiconductor layers 160B, which may reduce crystalline dislocation, reduce other crystalline defects, maximize strain (and thereby enhance carrier mobility, which increases drive current), or combinations thereof. In such embodiments, doped semiconductor layers 160B may be heavily doped semiconductor layers, and doped semiconductor layers 158B may be lightly doped semiconductor layers. In some embodiments, doped semiconductor layers 158B and doped semiconductor layers 160B have different semiconductor materials, which may have the same or different constituent concentrations. In some embodiments, doped semiconductor layers 156B include materials and/or dopants that provide compressive stress in channel layers 120B.

Doped semiconductor layers 158B may be deposited on and/or grown from channel layers 120B, and doped semiconductor layers 160B may be deposited on and/or grown from doped semiconductor layers 158B. In some embodiments, doped semiconductor layers 158B and doped semiconductor layers 160B are formed by respective SEG processes, which may implement CVD deposition techniques (e.g., VPE, UHV-CVD, LPCVD, PECVD, or the like), molecular beam epitaxy, other suitable SEG process, or combinations thereof. The SEG processes may use gaseous and/or liquid precursors that interact with the composition of channel layers 120B, doped semiconductor layers 158B, or combinations thereof. Epitaxial growth/deposition conditions, such as those described herein, are tuned to selectively deposit (grow) semiconductor material (e.g., silicon germanium) on semiconductor surfaces (e.g., channel layers 120B and/or doped semiconductor layers 158B) while limiting (or preventing) growth of semiconductor material from dielectric surfaces and/or non-semiconductor surfaces (e.g., inner spacers 149B, dummy gate stacks 132, gate spacers 134, substrate isolation structures 125, or combinations thereof). In some embodiments, doped semiconductor layers 158B and/or doped semiconductor layers 160B are doped during deposition (i.e., in-situ doping), such as by adding dopants to a source material of the SEG processes. In some embodiments, doped semiconductor layers 158B and/or doped semiconductor layers 160B are doped after deposition, such as by an ion implantation process. In some embodiments, annealing is performed to activate dopants in doped semiconductor layers 158B, doped semiconductor layers 160B, other source/drain regions, such as source/drain junction implants, or combinations thereof.

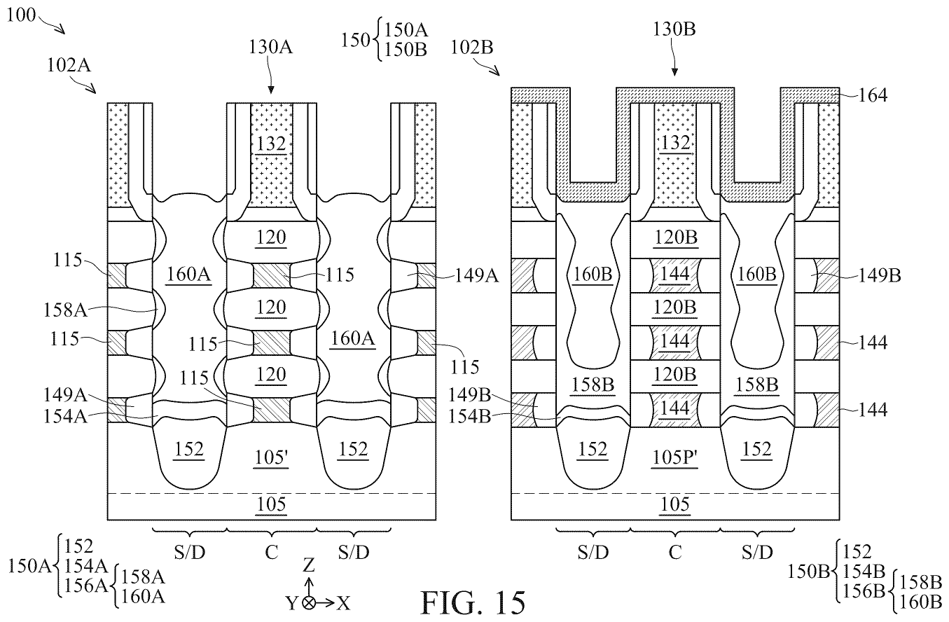

Referring to FIG. 15, mask 164 is removed from device region 102A by any suitable process (e.g., an etching process, a resist stripping process, other suitable process, or combinations thereof); a mask 164 is formed that covers device region 102B (e.g., a p-type transistor region), but not device region 102A (e.g., an n-type transistor region); and additional layers of source/drain structures 150A are formed in device region 102A. For example, mask 164 has an opening therein that overlaps device region 102A. Mask 164 may be formed in a manner similar to other masks described herein, such as mask 138 and/or mask 148. A composition of mask 164 is different than compositions of source/drain structures 150A (e.g., doped semiconductor layers 160A thereof), source/drain structures 150B (e.g., doped semiconductor layers 160B thereof), gate structures 130A, gate structures 130B, or combinations thereof to enable selective removal/etching therebetween. In some embodiments, mask 164 includes metal and oxygen and/or nitrogen (e.g., mask 164 is a metal oxide mask and/or a metal nitride mask). For example, mask 164 may include aluminum and oxygen and/or nitrogen, and mask 164 may be an aluminum oxide mask, an aluminum oxynitride mask, an aluminum nitride mask, or combinations thereof. In some embodiments, mask 164 is a patterned resist layer.

Insulator layers 154A may be formed in source/drain recesses 140A over undoped semiconductor layers 152 while device region 102B is covered by mask 164. Insulator layers 154A partially fill source/drain recesses 140A, and insulator layers 154A may be disposed on bottommost inner spacers 149A and/or mesas 105P′. Insulator layers 154A include an electrically insulating material, such as a dielectric material, that may reduce unwanted leakage current, such as current that may undesirably flow between doped semiconductor layers 156A through mesas 105P′. In some embodiments, insulator layers 154A include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. In some embodiments, insulator layers 154A include a metal-comprising dielectric material, such as a metal oxide material and/or a metal nitride material. In some embodiments, insulator layers 154A include a doped semiconductor material that includes an opposite type of dopant than doped semiconductor layers 156A. For example, in the depicted embodiment, where doped semiconductor layers 156A are portions of source/drains of n-type transistors (e.g., n-type doped semiconductor layers), insulator layers 154A may include a p-type doped semiconductor material, such as boron-doped silicon.

Insulator layers 154A may be formed by depositing an insulator material over device 100 and etching the insulator material, such that remainders of the insulator material fill bottoms of source/drain recesses 140A. The as-deposited insulator material may be disposed on tops of gate structures 130A (e.g., tops of gate spacers 134 and dummy gate stacks 132), sidewalls of gate structures 130B (e.g., of gate spacers 134), sidewalls of semiconductor layers 120, sidewalls of inner spacers 149A, sidewalls of mesas 105P′, and tops of mesa 105′ in source/drain regions. In some embodiments, as a result of properties of a deposition process (e.g., PVD), a thickness of the insulator material over horizontally oriented surfaces (e.g., tops of undoped semiconductor layers 152 in source/drain regions and tops of gate structures 130B) may be greater than a thickness of the insulator material over vertically oriented surfaces (e.g., sidewalls of gate structures 130B, sidewalls of semiconductor layers 120, and sidewalls of inner spacers 149A). Parameters of the etching may thus be tuned to remove vertically oriented portions of the insulator material, such as that on sidewalls of gate structures 130B, sidewalls of semiconductor layers 120, and sidewalls of inner spacers 149A. In such embodiments, as a result of etch loading effects, the etching may also remove horizontally oriented portions of the insulator material on top of gate structures 130B, but not (or minimally) horizontally oriented portions and/or vertically oriented portions of the insulator material in bottoms of source/drain recesses 140A, such as that disposed on undoped semiconductor layers 152 (i.e., the etching process may thin but not substantially remove such portions). In some embodiments, the as-deposited insulator material fills source/drain recesses 140A and the etching recesses the insulator material at least to bottom sacrificial semiconductor layers 115 and/or bottom inner spacers 149A. The etching may be a dry etch, a wet etch, other suitable etch, or combinations thereof.

Doped semiconductor layers 156A may also be formed in source/drain recesses 140A over insulator layers 154A and/or undoped semiconductor layers 152 while device region 102B is covered by mask 164. Doped semiconductor layers 156A fill remainders of source/drain recesses 140A, and doped semiconductor layers 156A are coupled to edges/ends of semiconductor layers 120. In the depicted embodiment, doped semiconductor layers 156A include doped semiconductor layers 158A and doped semiconductor layers 160A. Doped semiconductor layers 158A may be formed over semiconductor layers 120 and partially fill source/drain recesses 140A, and doped semiconductor layers 160A may be formed over doped semiconductor layers 158A and/or insulator layers 154A and fill remainders of source/drain recesses 140A. Doped semiconductor layers 158A are between semiconductor layers 120 and doped semiconductor layers 160A. In the depicted embodiment, doped semiconductor layers 158A are discontinuous and formed of discrete and separate portions, each of which is disposed on an end of a respective semiconductor layer 120 (i.e., portions of doped semiconductor layers 158A disposed on adjacent semiconductor layers 120 are not connected to one another). In such embodiment, doped semiconductor layers 160A may wrap doped semiconductor layers 158A, and doped semiconductor layers 160A may extend to and be disposed on inner spacers 149A. In some embodiments, one or more of the discrete, separate portions of doped semiconductor layers 158A may wrap a respective semiconductor layer 120, such that the discrete, separate portions are formed over a top and/or a bottom of the respective semiconductor layer 120. In some embodiments, the discrete, separate portions extend over and/or to inner spacers 149A. In some embodiments, one or more of the discrete, separate portions of doped semiconductor layers 158A are connected. In such embodiments, portions of doped semiconductor layers 160A may be separated from inner spacers 149A by doped semiconductor layers 158A.

Doped semiconductor layers 158A and doped semiconductor layers 160A include silicon, germanium, silicon germanium, other suitable semiconductor materials, or combinations thereof. In some embodiments, doped semiconductor layers 158A and doped semiconductor layers 160A include the same semiconductor material with different constituent concentrations. For example, doped semiconductor layers 158A and doped semiconductor layers 160A may include silicon and n-type dopant (e.g., phosphorous and/or arsenic), but different n-type dopant concentrations. In some embodiments, doped semiconductor layers 158A have a smaller n-type dopant concentration (e.g., P %) than doped semiconductor layers 160A, which may reduce crystalline dislocation, reduce other crystalline defects, maximize strain, or combinations thereof. In such embodiments, doped semiconductor layers 160A may be heavily doped semiconductor layers, and doped semiconductor layers 158A may be lightly doped semiconductor layers. In some embodiments, doped semiconductor layers 158A and doped semiconductor layers 160A have different semiconductor materials, which may have the same or different constituent concentrations. In some embodiments, doped semiconductor layers 156A include materials and/or dopants that provide tensile stress in semiconductor layers 120.

Doped semiconductor layers 158A may be deposited on and/or grown from semiconductor layers 120, and doped semiconductor layers 160A may be deposited on and/or grown from doped semiconductor layers 158A. In some embodiments, doped semiconductor layers 158A and doped semiconductor layers 160A are formed by respective SEG processes, which may implement CVD deposition techniques (e.g., VPE, UHV-CVD, LPCVD, PECVD, or the like), molecular beam epitaxy, other suitable SEG process, or combinations thereof. The SEG processes may use gaseous and/or liquid precursors that interact with the composition of semiconductor layers 120, doped semiconductor layers 158A, or combinations thereof. Epitaxial growth/deposition conditions, such as those described herein, are tuned to selectively deposit (grow) semiconductor material (e.g., silicon) on semiconductor surfaces (e.g., semiconductor layers 120 and/or doped semiconductor layers 158A) while limiting (or preventing) growth of semiconductor material from dielectric surfaces and/or non-semiconductor surfaces (e.g., inner spacers 149A, dummy gate stacks 132, gate spacers 134, substrate isolation structures 125, or combinations thereof). In some embodiments, doped semiconductor layers 158A and/or doped semiconductor layers 160A are doped during deposition (i.e., in-situ doping), such as by adding dopants to a source material of the SEG processes. In some embodiments, doped semiconductor layers 158A and/or doped semiconductor layers 160A are doped after deposition, such as by an ion implantation process. In some embodiments, annealing is performed to activate dopants in doped semiconductor layers 158A, doped semiconductor layers 160A, other source/drain regions, such as source/drain junction implants, or combinations thereof.

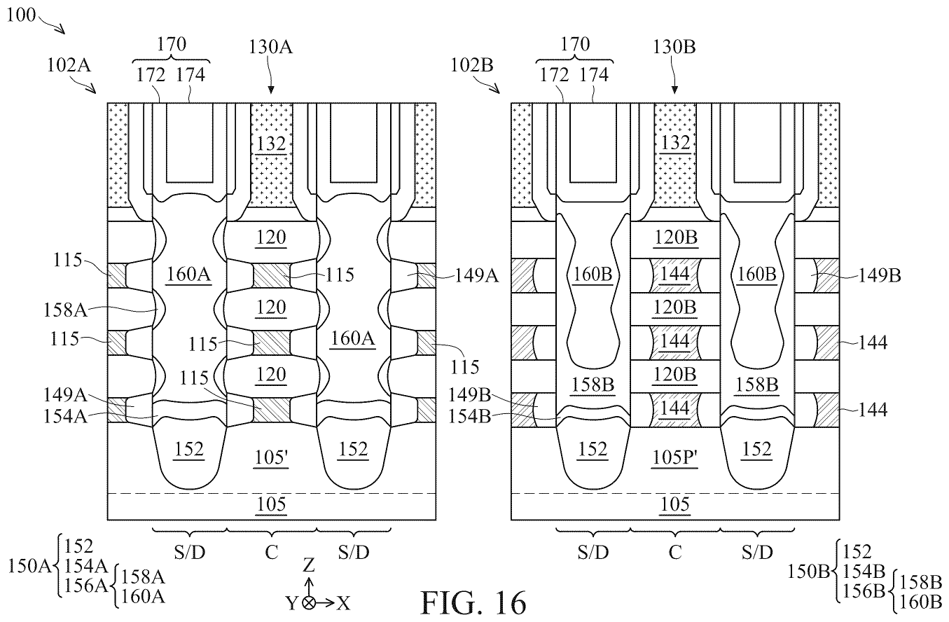

Referring to FIG. 16, fabrication of device 100 may include removing mask 164 by any suitable process and forming a dielectric layer 170 over source/drain structures 150. Dielectric layer 170 may fill spaces between adjacent gate structures, such as spaces between gate spacers 134 of adjacent gate structures 130A in device region 102A, spaces between gate spacers 134 of adjacent gate structure 130B in device region 102B, and spaces between adjacent source/drain structures 150. Forming dielectric layer 170 may include depositing a contact etch stop layer (CESL) 172, depositing an interlayer dielectric (ILD) layer 174 over the CESL, and performing a CMP and/or other planarization process until reaching dummy gate stacks 132. The planarization process may partially remove dummy gate stacks 132, such as hard masks thereof, to expose underlying dummy (e.g., poly) gates. The planarization process may reduce heights of dummy gate stacks 132 and/or gate spacers 134, in some embodiments.

ILD layer 174 includes a dielectric material including, for example, silicon oxide, carbon doped silicon oxide, silicon nitride, silicon oxynitride, tetraethylorthosilicate (TEOS)-formed oxide, BSG, PSG, borophosphosilicate glass, fluorosilicate glass, xerogel, aerogel, amorphous fluorinated carbon, parylene, benzocyclobutene-based (BCB) dielectric material, polyimide, other suitable dielectric material, or combinations thereof. In some embodiments, ILD layer 174 includes a low-k dielectric material having a dielectric constant that is less than a dielectric constant of silicon dioxide (e.g., k<3.9). In some embodiments, ILD layer 174 includes a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or combinations thereof, each of which is tuned/configured to exhibit a dielectric constant less than about 2.5. CESL 172 includes a material different than ILD layer 174, such as a dielectric material that is different than the dielectric material of ILD layer 174. For example, where ILD layer 174 includes a silicon-and-oxygen comprising low-k dielectric material, CESL 172 may include silicon and nitrogen, such as silicon nitride or silicon oxynitride. ILD layer 174 and/or CESL 172 may have a multilayer structure and/or include multiple dielectric materials.

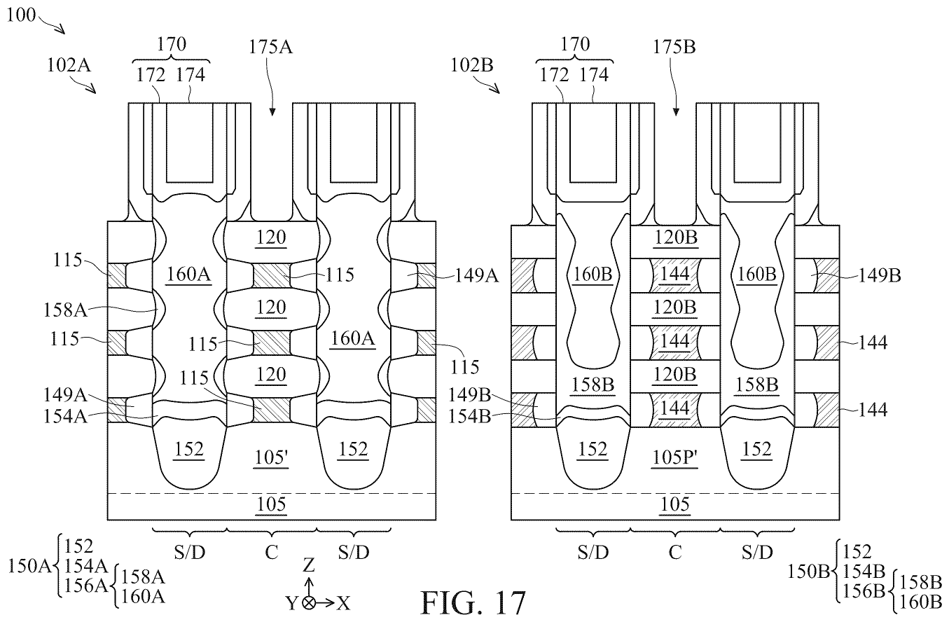

Referring to FIGS. 17-22, fabrication of device 100 may include a gate replacement process, which replaces dummy gate stacks 132 and sacrificial semiconductor layers 115 with gate stacks 180A in device region 102A and dummy gate stacks 132 and sacrificial oxide layers 144 with gate stacks 180B in device region 102B. Gate stacks 180A (also referred to as high-k/metal gates) are disposed between respective gate spacers 134, between respective inner spacers 149A, between respective channel layers 120A (described further below), and between respective channel layers 120A and respective mesas 105P′. Gate stacks 180B (also referred to as high-k/metal gates) are disposed between respective gate spacers 134, between respective inner spacers 149B, between respective channel layers 120B, and between respective channel layers 120B and respective mesas 105P′. Each gate stack 180A may include a respective gate dielectric 182A and a respective gate electrode 184A, and each gate stack 180B may include a respective gate dielectric 182B and a respective gate electrode 184B.

Referring to FIG. 17, dummy gate stacks 132 are removed from gate structures 130A to form gate openings 175A in device region 102A, and dummy gate stacks 132 are removed from gate structures 130B to form gate openings 175B in device region 102B. Gate openings 175A expose channel regions in device region 102A, which include semiconductor layers 120 and sacrificial semiconductor layers 115. Gate openings 175B expose channel regions in device region 102B, which include channel layers 120B and sacrificial oxide layers 144. In some embodiments, an etching process selectively removes dummy gate stacks 232 (e.g., poly gates) with negligible (to no) removal of dielectric layer 170, gate spacers 134, inner spacers 149A, inner spacers 149B, sacrificial oxide layers 144, semiconductor layers 120, channel layers 120B, sacrificial semiconductor layers 115, or combinations thereof. The etching process is a dry etch, a wet etch, other suitable etch process, or combinations thereof. In some embodiments, the etching process uses a patterned mask layer as an etch mask, where the patterned mask layer covers dielectric layer 170 and/or gate spacers 134. In some embodiments, dummy gate dielectric layers (e.g., dummy oxide layers) of dummy gate stacks 132 remain.

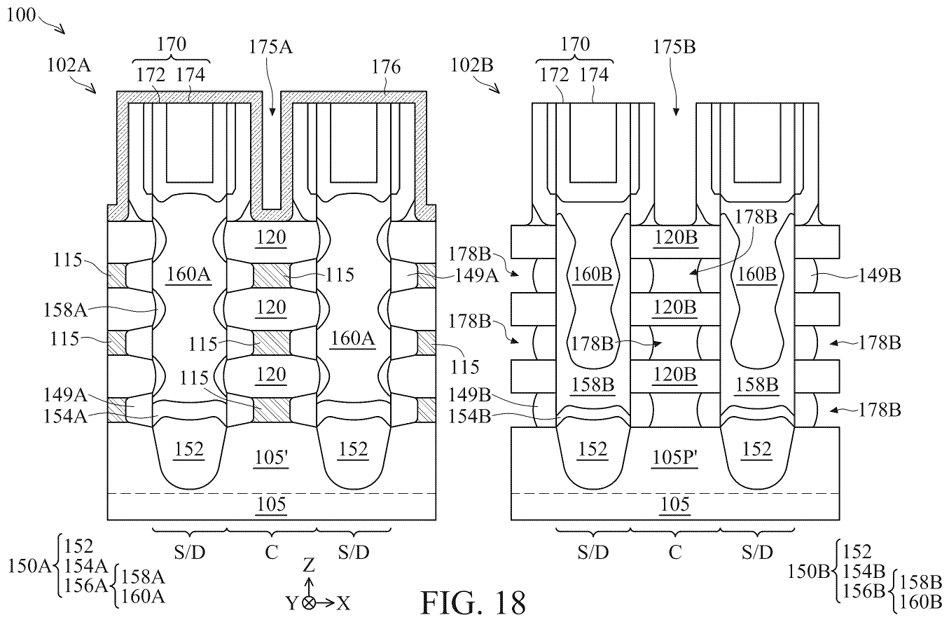

Referring to FIG. 18, a mask 176 is formed over device 100 that covers device region 102A (e.g., an n-type transistor region), but not device region 102B (e.g., a p-type transistor region). For example, mask 176 has an opening therein that overlaps device region 102B. Mask 176 may be formed in a manner similar to other masks described herein, such as mask 138 and/or mask 148. A composition of mask 176 is different than compositions of gate dielectrics 182B (e.g., high-k dielectric layers thereof), dielectric layer 170, sacrificial oxide layers 144, gate spacers 134, semiconductor layers 120, or combinations thereof to enable selective removal/etching therebetween. In some embodiments, mask 176 includes metal and oxygen and/or nitrogen (e.g., mask 176 is a metal oxide mask and/or a metal nitride mask). For example, mask 176 may include aluminum and oxygen and/or nitrogen, and mask 176 may be an aluminum oxide mask, an aluminum oxynitride mask, an aluminum nitride mask, or combinations thereof. In some embodiments, mask 176 is a patterned resist layer.

After forming mask 176, sacrificial oxide layers 144 are removed from channel regions in device region 102B, thereby forming gaps (openings) 178B that expose channel layers 120B. Gate openings 175B are thus extended between channel layers 120B and between channel layers 120B and mesas 105P′. In some embodiments, an etching process selectively removes sacrificial oxide layers 144 with respect to mesas 105P′, channel layers 120B, gate spacers 134, inner spacers 149B, dielectric layer 170, mask 176, or combinations thereof. In other words, the etching process removes sacrificial oxide layers 144 with negligible (to no) removal of mesas 105P′, channel layers 120B, gate spacers 134, inner spacers 149B, dielectric layer 170, mask 176, or combinations thereof. For example, an etchant is selected for the etching process that etches an oxide material (e.g., sacrificial oxide layers 144) at a higher rate than silicon (e.g., channel layers 120B and mesas 105P′) and dielectric materials having compositions different than the oxide material (e.g., gate spacers 134, inner spacers 149B, CESL 172, ILD layer 174, etc.) (i.e., the etchant has a high etch selectivity with respect to the oxide material). The etching process is a dry etch, a wet etch, other suitable etch, or combinations thereof. In some embodiments, the etching process removes any remainder of dummy gate stacks 232, such as dummy gate dielectric layers thereof (e.g., dummy oxide layers).

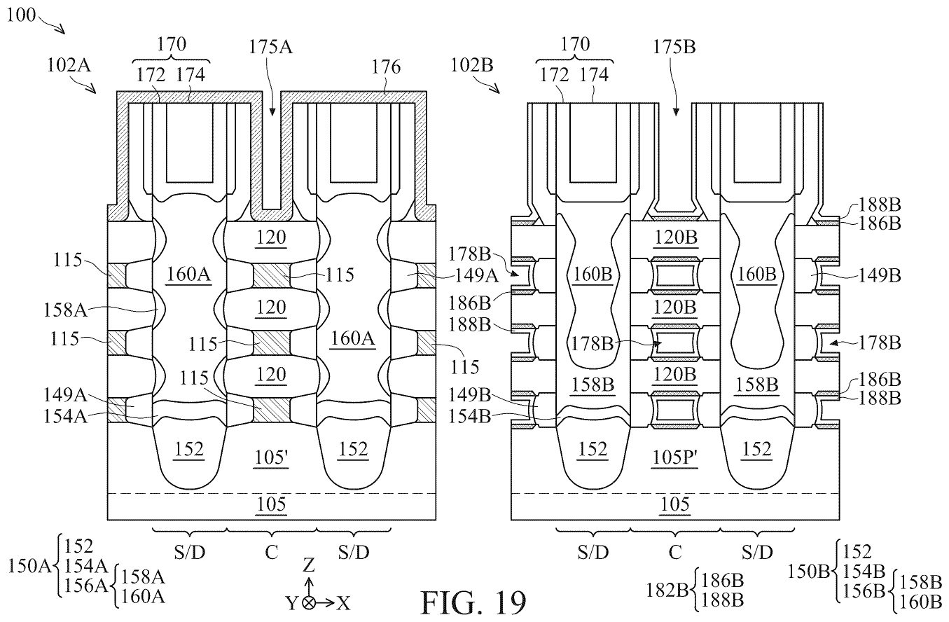

Referring to FIG. 19, gate dielectrics 182B are formed in and partially fill gate openings 175B and gaps 178B. Gate dielectrics 182B are disposed on respective channel layers 120B, respective inner spacers 149B, respective gate spacers 134, substrate isolation structures 125, or combinations thereof. Gate dielectrics 182B include at least one dielectric layer, such as an interfacial layer 186B and/or a high-k dielectric layer 188B. Interfacial layers 186B include a dielectric material, such as SiO₂, SiGeOₓ, HfSiO, SiON, other dielectric material, or combinations thereof. Interfacial layers 186B are formed by thermal oxidation, chemical oxidation, ALD, CVD, other process, or combinations thereof. High-k dielectric layers 188B include a high-k dielectric material, which generally refers to a dielectric material having a dielectric constant greater than a dielectric constant of silicon dioxide, such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr) TiO₃ (BST), HfO₂—Al₂O₃, other high-k dielectric material, or combinations thereof. High-k dielectric layers 188B are formed by ALD, CVD, PVD, an oxide-based deposition process, other process, or combinations thereof. In some embodiments, after deposition of gate dielectric material (e.g., high-k dielectric layers and/or interfacial layers), a planarization process (e.g., CMP) may be performed to remove portions of the gate dielectric material over dielectric layer 170 and/or mask 176. In some embodiments, high-k dielectric layers 188B include a hafnium-based oxide (e.g., HfO₂) layer. In some embodiments, high-k dielectric layers 188B include a zirconium-based oxide (e.g., ZrO₂) layer.

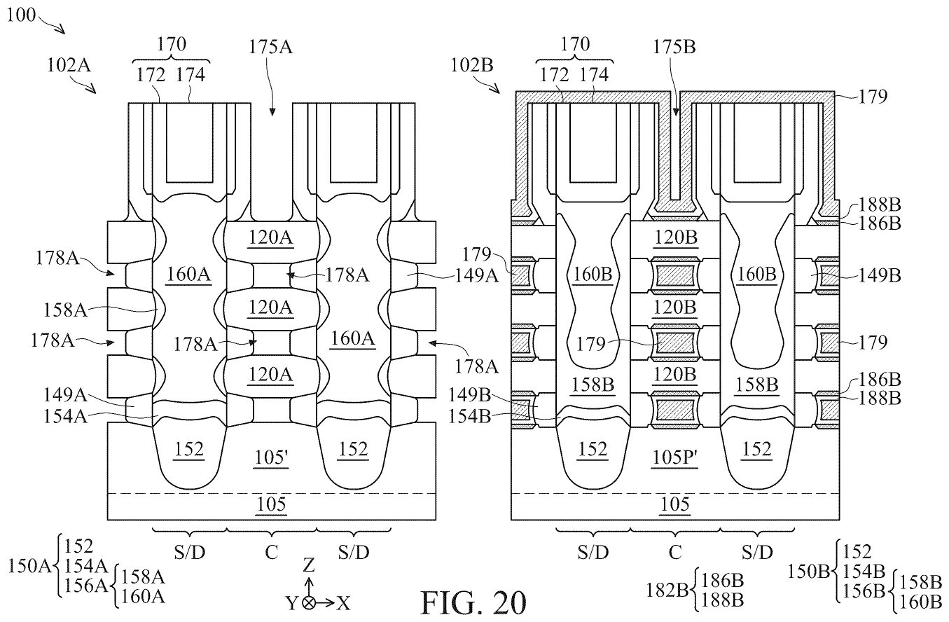

Referring to FIG. 20, mask 176 is removed from device region 102A by any suitable process (e.g., an etching process, a resist stripping process, other suitable process, or combinations thereof) and a mask 179 is formed over device 100 that covers device region 102B (e.g., a p-type transistor region), but not device region 102A (e.g., an n-type transistor region). For example, mask 179 has an opening therein that overlaps device region 102A. Mask 179 may be formed in a manner similar to other masks described herein, such as mask 138 and/or mask 148. A composition of mask 179 is different than compositions of gate dielectrics 182B (e.g., high-k dielectric layers 188B thereof), dielectric layer 170, inner spacers 149A, gate spacers 134, semiconductor layers 120, sacrificial semiconductor layers 115, or combinations thereof to enable selective removal/etching therebetween. In some embodiments, mask 179 includes metal and oxygen and/or nitrogen (e.g., mask 179 is a metal oxide mask and/or a metal nitride mask). For example, mask 179 may include aluminum and oxygen and/or nitrogen, and mask 179 may be an aluminum oxide mask, an aluminum oxynitride mask, an aluminum nitride mask, or combinations thereof. In some embodiments, mask 179 is a patterned resist layer.

After forming mask 179, a channel release process may be performed to form suspended channel layers in device region 102A. For example, an etching process selectively removes sacrificial semiconductor layers 115 exposed by gate openings 175A, thereby forming gaps (openings) 178A in channel regions in device region 102A. Gate openings 175A are thus extended between semiconductor layers 120 and between semiconductor layers 120 and mesas 105P′. The etching process may selectively remove sacrificial semiconductor layers 115 with respect to mesas 105P′, semiconductor layers 120, gate spacers 134, inner spacers 149A, dielectric layer 170, mask 179, or combinations thereof. In other words, the etching process removes sacrificial semiconductor layers 115 with negligible (to no) removal of mesas 105P′, semiconductor layers 120, gate spacers 134, inner spacers 149A, dielectric layer 170, mask 179, or combinations thereof. In some embodiments, an etchant is selected for the etching process that etches silicon germanium (e.g., sacrificial semiconductor layers 115) at a higher rate than silicon (e.g., semiconductor layers 120 and mesas 105P′), dielectric materials (e.g., gate spacers 134, inner spacers 149A, and dielectric layer 170), and mask 179. The etching process is a dry etch, a wet etch, other suitable etch, or combinations thereof. In some embodiments, before the etching process, an oxidation process may be performed to convert sacrificial semiconductor layers 115 into semiconductor oxide layers (e.g., silicon germanium oxide layers). In such embodiments, the etching process removes semiconductor oxide layers to form gaps 178A. In some embodiments, the etching process removes any remainder of dummy gate stacks 232, such as dummy gate dielectric layers thereof (e.g., dummy oxide layers).

Semiconductor layers 120 remaining in channel regions are suspended over mesas 105P′ after removing sacrificial semiconductor layers 115. In the depicted embodiment, each channel region in device region 102A has three suspended semiconductor layers 120, which are referred to hereafter as channel layers 120A. Channel layers 120A are vertically stacked along the z-direction, and channel layers 120A may provide three channels through which current can flow between respective source/drain structures 150A. In some embodiments, after removing sacrificial semiconductor layers 115, an etching process may be performed to modify a profile of channel layers 120A to provide target dimensions and/or target shapes thereof. For example, the etching process may provide channel layers 120A with cylindrical-shaped profiles (e.g., nanowires), rectangular-shaped profiles (e.g., nanobars), sheet-shaped profiles (e.g., nanosheets (e.g., dimensions in the X-Y plane are sufficiently greater than dimensions in the X-Z plane and the Y-Z plane to form sheet-like structures)), or any other suitable shaped profile. In some embodiments, channel layers 120A have nanometer-sized dimensions and may be referred to as “nanostructures,” alone or collectively. In some embodiments, channel layers 120A have sub-nanometer dimensions and/or other suitable dimensions.

Because sacrificial semiconductor layers 115 are replaced with sacrificial oxide layers 144 in device region 102B before source/drain fabrication, constituents from sacrificial layers/dummy interposers (e.g., sacrificial semiconductor layers 115 and/or sacrificial oxide layers 144) will not migrate into channel layers 120B during fabrication of source/drain structures 150B and/or source/drain structures 150B, such as migration of germanium that may occur during thermal processes associated with such fabrication. Reducing and/or preventing migration of constituents (e.g., germanium) from the sacrificial layers/dummy interposers hinders undesired changes in stress characteristics of channel layers 120B, such as the undesired introduction of tensile stress (e.g., along the x-direction) in compressively stressed channel layers 120B, that may negatively impact performance of the p-type transistors. P-type transistors fabricated according to the disclosed methods (e.g., which implement sacrificial oxide layers 144) in p-type transistor regions thus exhibit improved performance, such as less channel resistance and/or improved stress characteristics (e.g., minimal to no tensile stress).

In contrast, sacrificial semiconductor layers 115 introduce additional tensile stress (e.g., along the x-direction) in tensely stressed channel layers 120A that may improve performance of n-type transistors, such as less channel resistance and/or improved stress characteristics (e.g., increase in tensile stress). Because sacrificial semiconductor layers 115 remain in device region 102A during source/drain fabrication, constituents from sacrificial semiconductor layers 115 (e.g., germanium) may migrate into channel layers 120A during fabrication of source/drain structures 150B and/or source/drain structures 150A. In some embodiments, it may be desired to remove portions of channel layers 120A having sacrificial layer constituents (e.g., germanium). In such embodiments, a trimming process may be performed on channel layers 120A after forming gaps 178A to remove portions of channel layers 120A having the sacrificial layer constituents (e.g., germanium). In some embodiments, the trimming process is an etching process, such as a wet etch. In some embodiments, a thickness of channel layers 120A in gate regions (e.g. portions between gaps 178A) may be less than a thickness of channel layers 120A in inner spacer regions (e.g., portions between inner spacers 149A) after the trimming process. In such embodiments, thicknesses of channel layers 120A in gate regions are less than thicknesses of channel layers 120B in gate regions. In some embodiments, the thickness of the channel layers 120A in the gate regions is about 2 nm to about 12 nm after the trimming process. In some embodiments, the trimming process includes oxidizing germanium-containing portions of channel layers 120A (i.e., those portions of channel layers 120A that include germanium, which may have migrated from sacrificial semiconductor layers 115 into channel layers 120A during thermal processes, such as those associated with source/drain formation) and etching the oxidized germanium-containing portions of channel layers 120A (e.g., by wet etch). In some embodiments, after the trimming process, a thickness of channel layers 120A in the gate regions may be increased by forming semiconductor layers (e.g., silicon layers) over exposed portions of channel layers 120A (e.g., tops and bottoms thereof in the gate regions), such that channel layers 120A have substantially uniform thicknesses along their lengths. In such embodiments, thicknesses of channel layers 120A may be substantially the same as or greater than thicknesses of channel layers 120B. The semiconductor layers may be formed by an epitaxial growth process and/or other suitable deposition process.

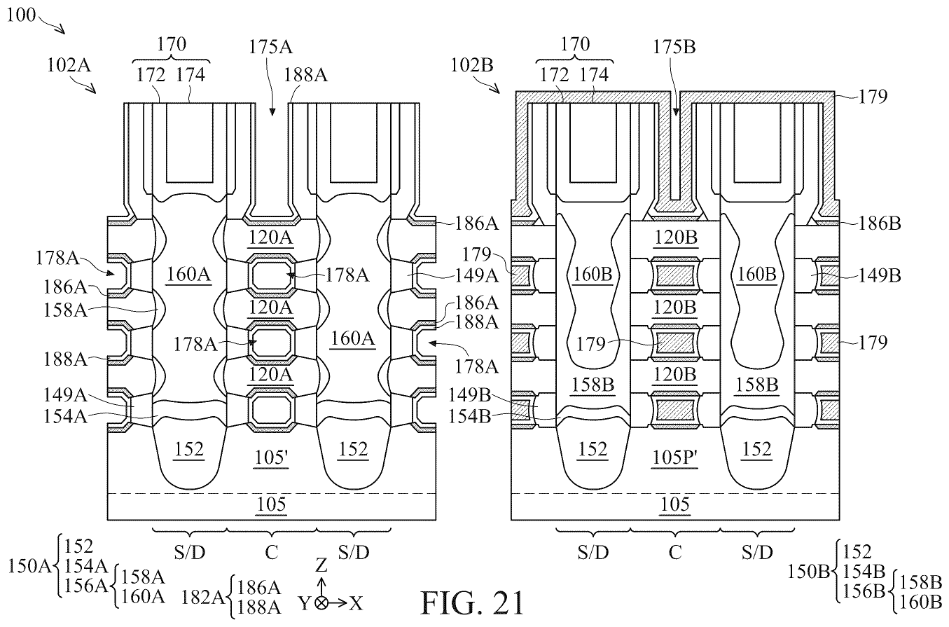

Referring to FIG. 21, gate dielectrics 182A are formed in and partially fill gate openings 175A and gaps 178A. Gate dielectrics 182A are disposed on respective channel layers 120A, respective inner spacers 149A, respective gate spacers 134, substrate isolation structures 125, or combinations thereof. Gate dielectrics 182A include at least one dielectric layer, such as an interfacial layer 186A and/or a high-k dielectric layer 188A. Interfacial layers 186A include a dielectric material, such as SiO₂, SiGeOₓ, HfSiO, SiON, other dielectric material, or combinations thereof. Interfacial layers 186A are formed by thermal oxidation, chemical oxidation, ALD, CVD, other process, or combinations thereof. High-k dielectric layers 188A include a high-k dielectric material, which generally refers to a dielectric material having a dielectric constant greater than a dielectric constant of silicon dioxide, such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr) TiO₃ (BST), HfO₂—Al₂O₃, other high-k dielectric material, or combinations thereof. High-k dielectric layers 188A are formed by ALD, CVD, PVD, an oxide-based deposition process, other process, or combinations thereof. In some embodiments, after deposition of gate dielectric material (e.g., high-k dielectric layers and/or interfacial layers), a planarization process (e.g., CMP) may be performed to remove portions of the gate dielectric material over dielectric layer 170 and/or mask 179. In some embodiments, high-k dielectric layers 188A include a hafnium-based oxide (e.g., HfO₂) layer. In some embodiments, high-k dielectric layers 188A include a zirconium-based oxide (e.g., ZrO₂) layer.

Referring to FIG. 22, after removing mask 179 from device region 102B by any suitable process (e.g., an etching process, a resist stripping process, other suitable process, or combinations thereof), gate electrodes 184A are formed in and fill remainders of gate openings 175A and gaps 178A, and gate electrodes 184B are formed in and fill remainders of gate openings 175B and gaps 178B. Gate electrodes 184A are disposed over respective gate dielectrics 182A, and gate electrodes 184B are disposed over respective gate dielectrics 182B. In some embodiments, gate electrodes 184A and gate electrodes 184B include an electrically conductive layer formed of an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, the electrically conductive layer includes a work function layer, which may be tuned to have a desired work function (e.g., an n-type work function or a p-type work function). The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, the electrically conductive layer includes a bulk layer over the gate dielectric and/or the work function layer. The bulk layer may include Al, W, Cu, Ti, Ta, TiN, TaN, polysilicon, other suitable metal(s) and/or alloys thereof, or combinations thereof. In some embodiments, the electrically conductive layer includes a barrier layer over the work function layer and/or the gate dielectric. The barrier layer includes a material that may prevent diffusion and/or reaction of constituents between adjacent layers and/or promote adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

In the depicted embodiment, gate electrodes 184A and gate electrodes 184B are formed simultaneously, for example, by depositing gate electrode material (e.g., work function layers, barrier layers, bulk layers, etc.) over device 100 that fill remainders of gate openings 175A, gate openings 175B, gaps 178A, and gaps 178B, and performing a planarization process (e.g., CMP) to remove portions of the gate electrode material over dielectric layer 170. In some embodiments, gate electrodes 184A and gate electrodes 184B may be formed separately. For example, gate electrodes 184B may be formed after gate dielectrics 182B while mask 176 covers device region 102A, and gate electrodes 184A may be formed after gate dielectrics 182A while mask 179 covers device region 102B. In some embodiments, gate electrodes 184A and gate electrodes 184B may be formed partially simultaneously and partially separately. For example, work function layers (or sublayers thereof) thereof of gate electrodes 184B may be formed after gate dielectrics 182B while mask 176 covers device region 102A, work function layers (or sublayers thereof) thereof of gate electrodes 184A may be formed after gate dielectrics 182A while mask 179 covers device region 102B, and bulk layers of gate electrodes 184A and bulk layers of gate electrodes 184B may be formed at the same time after removing mask 179. In other words, work function layers of gate electrodes 184A are formed with gate dielectrics 182A, and work function layers of gate electrodes 184B are formed with gate dielectrics 182B.

Gate stacks 180A and gate stacks 180B are configured to achieve desired functionality according to design requirements of device 100, and gate stacks 180A and gate stacks 180B may have different layers in different device regions. For example, compositions and/or configurations of gate dielectrics 182A and gate dielectrics 182B may be the same or different, and compositions and/or configurations of gate electrodes 184A and gate electrodes 184B may be the same or different. In some embodiments, a number, configuration, materials, or combinations thereof of layers of gate dielectrics 182A corresponding with device region 102A (e.g., an n-type transistor region) may be different than a number, configuration, materials, or combinations thereof of layers of gate dielectrics 182B corresponding with device region 102B (e.g., a p-type transistor region). In some embodiments, a number, configuration, materials, or combinations thereof of layers of gate electrodes 184A corresponding with device region 102A may be different than a number, configuration, materials, or combinations thereof of layers of gate electrodes 184B corresponding with device region 102B.

Fabrication of device 100 may further include etching back gate stacks 180A and gate stacks 180B and forming hard masks (e.g., self-aligned cap structures) over the etched-back gate stacks 180A, 180B. The hard masks include a material that is different than dielectric layer 170 and/or subsequently formed dielectric layers to achieve etch selectivity. In some embodiments, the hard masks include silicon and nitrogen and/or carbon, such as silicon nitride, silicon oxynitride, silicon carbide, silicon oxycarbide, silicon carbonitride, silicon oxycarbonitride, or combinations thereof. In some embodiments, the hard masks include metal and oxygen and/or nitrogen, such as aluminum oxide, aluminum nitride, aluminum oxynitride, zirconium oxide, zirconium nitride, hafnium oxide, zirconium aluminum oxide, or combinations thereof.

Referring to FIGS. 22-28, device 100 may thus include various transistors, such as n-type transistors in device region 102A and p-type transistors in device region 102B. An n-type transistor may include respective channels (e.g., channel layers 120A), source/drains (e.g., source/drain structures 150A), and a respective gate (e.g., gate stack 180A); and a p-type transistor may include respective channels (e.g., channel layers 120B), source/drains (e.g., source/drain structures 150B), and a respective gate (e.g., gate stack 180B). Gate stacks 180A are disposed between respective source/drains (e.g., source/drain structures 150A) along the x-direction, and inner spacers 149A are disposed between gate stacks 180A and their respective source/drains; and gate stacks 180B are disposed between respective source/drains (e.g., source/drain structures 150B) along the x-direction, and inner spacers 149B are disposed between gate stacks 180B and their respective source/drains. Further, gate stacks 180A engage respective channels (e.g., channel layers 120A), and the respective channels extend between the respective source/drains (e.g., source/drain structures 150A) along the x-direction, and gate stacks 180B engage respective channels (e.g., channel layers 120B), and the respective channels extend between the respective source/drains (e.g., source/drain structures 150B) along the x-direction. In the depicted embodiment, the n-type transistor and the p-type transistor are GAA transistors. Gate stacks 180A may thus surround their respective channel layers, and along the gate lengthwise direction, each gate stack 180A may include a gate dielectric (e.g., gate dielectric 182A) and a gate electrode (e.g., gate electrode 184A) that surrounds its respective channels. Gate stacks 180B may also surround their respective channel layers, and along the gate lengthwise direction, each gate stack 180B may include a gate dielectric (e.g., gate dielectric 182B) and a gate electrode (e.g., gate electrode 184B) that surrounds its respective channels. In some embodiments, gate stacks 180A and gate stacks 180B may wrap and/or partially surround their respective channel layers (i.e., disposed on at least two sides thereof), such as where the n-type transistor and the p-type transistor are fork-sheet transistors or other multigate transistors.

Implementing disposable/dummy interposers having different compositions (e.g., sacrificial semiconductor layers 115 in device region 102A and sacrificial oxide layers 144 in device region 102B) may provide differently configured channels in device region 102A (e.g., the n-type transistor region) and device region 102B (e.g., the p-type transistor region). For example, because of etch selectivity differences associated with disposable semiconductor interposers (DSIs) (e.g., sacrificial semiconductor layers 115) and disposable oxide interposers (DOIs) (e.g., sacrificial oxide layers 144), the channels may have different cross-sectional profiles, such as channel layers 120B that are relatively square-shaped in device region 102B (e.g., the p-type transistor region) and channel layers 120A that are relatively oval-shaped in device region 102A (e.g., the n-type transistor region). Such channel profile differences may also, additionally or alternatively, result from performing a trimming process after forming gaps 178A (FIG. 20) and before forming gate dielectrics 182A (FIG. 21), but not after forming gaps 178B (FIG. 18) and before forming gate dielectrics 182B (FIG. 19). Further, thicknesses T1 of channel layers 120B in device region 102B may be relatively uniform along their lengths (e.g., a thickness of the channel layers 120B in inner spacer regions may be substantially the same as a thickness of the channel layers 120B in the gate region), while thicknesses T2 of channel layers 120A in device region 102A may vary along their lengths (e.g., a thickness of channel layers 120A in inner spacer regions may be greater than a thickness of channel layers 120A in the gate region). Further, the inner spacers may have different cross-sectional profiles, such as inner spacers 149B having widths that vary along their heights/thicknesses in device region 102B (e.g., the p-type transistor region) and inner spacers 149A having heights/thicknesses that vary along their widths in device region 102A (e.g., the n-type transistor region).

Implementing disposable/dummy interposers having different compositions may also provide device region 102A (e.g., the n-type transistor region) and device region 102B (e.g., the p-type transistor region) with different types of channel residue, such as depicted in FIG. 28. For example, residual oxide 144R (e.g., residual silicon oxide) may remain between inner spacers 149B and gate stack 180B and/or between inner spacers 149B and channel layers 120B in device region 102B (e.g., the p-type transistor region) and residual semiconductor 115R (e.g., residual silicon germanium) may remain between inner spacers 149A and gate stack 180A and/or between inner spacers 149A and channel layers 120A in device region 102A (e.g., the n-type transistor region). Residual oxide 144R may be portions of sacrificial oxide layers 144 that are not removed by the etching process when forming gaps 178B during the gate replacement process (e.g., FIG. 18), and residual semiconductor 115R may be portions of sacrificial semiconductor layers 115 that are not removed by the etching process when forming gaps 178A during the gate replacement process (e.g., FIG. 20). In some embodiments, residual oxide 144R has an oxygen concentration that is about 50% to about 70%. In some embodiments, residual semiconductor 115R has a germanium concentration that is about 10% to about 50%.

Further, as described herein, implementing disposable/dummy interposers having different compositions (e.g., sacrificial semiconductor layers 115 in device region 102A and sacrificial oxide layers 144 in device region 102B) may optimize stress characteristics and/or performance of n-type transistors and p-type transistors. For example, implementing sacrificial semiconductor layers 115 in device region 102A (e.g., the n-type transistor region) and replacing sacrificial semiconductor layers 115 with sacrificial oxide layers 144 in device region 102B (e.g., the p-type transistor region) imparts stress (e.g., tensile stress along the x-direction) to channel layers 120A that may boost performance of the n-type transistors (e.g., by reducing channel resistance) without imparting such stress to channel layers 120B, thereby preserving desired stress characteristics and thus performance of p-type transistors in device region 102B.

The present disclosure provides for many different embodiments. An exemplary method includes forming a semiconductor layer stack that includes first semiconductor layers and second semiconductor layers in an interleaving pattern, patterning the semiconductor layer stack to form a first semiconductor stack in a first device region and a second semiconductor stack in a second device region, and forming first source/drain recesses and second source/drain recesses. A portion of the first semiconductor stack is disposed between the first source/drain recesses, and a portion of the second semiconductor stack is disposed between the second source/drain recesses. The method further includes recessing the second semiconductor layers of the portion of the first semiconductor stack to form first inner spacer gaps after forming the first source/drain recesses, replacing the second semiconductor layers of the portion of the second semiconductor stack with oxide layers and recessing the oxide layers to form second inner spacer gaps after forming the second source/drain recesses, and forming first inner spacers in the first inner spacer gaps and second inner spacers in the second inner spacer gaps. The method further includes, after forming the first inner spacers and the second inner spacers, replacing the second semiconductor layers of the portion of the first semiconductor stack with a first gate stack and the oxide layers of the portion of the second semiconductor stack with a second gate stack.

In some embodiments, the first device region is an n-type transistor region, and the second device region is a p-type transistor region. In some embodiments, the method includes forming a first mask over the first device region when forming the first source/drain recesses and recessing the second semiconductor layers of the portion of the first semiconductor stack to form the first inner spacer gaps and forming a second mask over the second device region when forming the second source/drain recesses, replacing the second semiconductor layers of the portion of the second semiconductor stack with the oxide layers, and recessing the oxide layers to form the second inner spacer gaps.

In some embodiments, the method includes forming a first dummy gate over the first semiconductor stack and a second dummy gate over the second semiconductor stack before forming the first source/drain recesses and the second source/drain recesses. In some embodiments, the method includes simultaneously removing the first dummy gate to form a first gate opening and the second dummy gate to form a second gate opening. The first dummy gate and the second dummy gate may be removed after replacing the second semiconductor layers of the portion of the second semiconductor stack with oxide layers and before replacing the second semiconductor layers of the portion of the first semiconductor stack with the first gate stack and the oxide layers of the portion of the second semiconductor stack with the second gate stack.

In some embodiments, the method includes simultaneously forming the first inner spacers and the second inner spacers. In some embodiments, the method includes separately forming the first inner spacers and the second inner spacers. In some embodiments, recessing the second semiconductor layers of the portion of the first semiconductor stack to form the first inner spacer gaps includes performing a first etching process having a first etch selectivity between the second semiconductor layers and the first semiconductor layers. In some embodiments, recessing the oxide layers to form the second inner spacer gaps includes performing a second etching process having a second etch selectivity between the oxide layers and the first semiconductor layers. A difference between the second etch selectivity and the first etch selectivity may provide the first inner spacer gaps with a first profile and the second inner spacer gaps with a second profile that is different than the first profile.

In some embodiments, replacing the second semiconductor layers of the portion of the first semiconductor stack with the first gate stack includes selectively removing the second semiconductor layers of the portion of the first semiconductor stack to form first gate gaps between the first semiconductor layers of the portion of the first semiconductor stack, forming a first gate dielectric that partially fills the first gate gaps, and forming a first gate electrode that fills a remainder of the first gate gaps. In such embodiments, the first gate dielectric and the first gate electrode may provide the first gate stack in the first device region. In some embodiments, replacing the oxide layers of the portion of the second semiconductor stack with the second gate stack includes selectively removing the oxide layers of the portion of the second semiconductor stack to form second gate gaps between the first semiconductor layers of the portion of the second semiconductor stack, forming a second gate dielectric that partially fills the second gate gaps, and forming a second gate electrode that fills a remainder of the second gate gaps. In such embodiments, the second gate dielectric and the second gate electrode may provide the second gate stack in the second device region. In some embodiments, the method includes forming a third mask over the second device region when selectively removing the second semiconductor layers and forming the first gate dielectric. In some embodiments, the method includes forming a fourth mask over the first device region when selectively removing the oxide layers and forming the second gate dielectric. In some embodiments, the method includes forming the first gate electrode and the second gate electrode simultaneously.

Another exemplary method includes forming a first multilayer stack in a first device region and a second multilayer stack in a second device region. Each of the first multilayer stack and the second multilayer stack includes sacrificial semiconductor layers and semiconductor layers. The method further includes removing the sacrificial semiconductor layers of the first multilayer stack to form first gaps between the semiconductor layers of the first multilayer stack, forming sacrificial oxide layers in the first gaps, recessing the sacrificial oxide layers to form first inner spacer notches between the semiconductor layers of the first multilayer stack, and recessing the sacrificial semiconductor layers to form second inner spacer notches between the semiconductor layers of the second multilayer stack. Th method further includes removing the sacrificial oxide layers to form second gaps between the semiconductor layers of the first multilayer stack after forming first inner spacers in the first inner spacer notches, removing the sacrificial semiconductor layers to form third gaps between the semiconductor layers of the second multilayer stack after forming second inner spacers in the second inner spacer notches, and forming a first gate stack in the second gaps and a second gate stack in the third gaps. In some embodiments, the method includes forming a first gate electrode of the first gate stack in the second gaps and forming a second gate electrode of the second gate stack in the third gaps. In some embodiments, the method includes forming a first dummy gate over the first multilayer stack, forming a second dummy gate over the second multilayer stack, and removing the first dummy gate and the second dummy gate before removing the sacrificial oxide layers to form the second gaps and removing the sacrificial semiconductor layers to form the third gaps.

In some embodiments, the method includes masking the second device region when removing the sacrificial semiconductor layers of the first multilayer stack to form the first gaps, forming the sacrificial oxide layers in the first gaps, and recessing the sacrificial oxide layers to form first inner spacer notches. In some embodiments, the method includes masking the first device region when recessing the sacrificial semiconductor layers to form the second inner spacer notches. In some embodiments, the method includes masking the second device region when removing the sacrificial oxide layers to form the second gaps and forming a first gate dielectric of the first gate stack in the second gaps and masking the first device region when removing the sacrificial semiconductor layers to form third gaps and forming a second gate dielectric of the second gate stack in the third gaps.

In some embodiments, forming the first inner spacers and forming the second inner spacer includes depositing a dielectric material over the first device region and the second device region and etching the dielectric material. The dielectric material at least partially fills the first inner spacer notches and the second inner spacer notches. In some embodiments, the first inner spacer notches have a first profile, the second inner spacer notches have a second profile, and the second profile is different than the first profile. In some embodiments, the first device region is a p-type transistor region, and the second device region is an n-type transistor region.

An exemplary device structure includes a p-type transistor and an n-type transistor. The p-type transistor includes a first semiconductor layer disposed between first source/drain structures, a first gate stack, first gate spacers, and first inner spacers. The n-type transistor includes a second semiconductor layer disposed between second source/drain structures, a second gate stack, second gate spacers, and second inner spacers. The first gate stack is disposed over the first semiconductor layer, the first gate stack is disposed between the first source/drain structures, the second gate stack is disposed over the second semiconductor layer, and the second gate stack is disposed between the second source/drain structures. The first gate spacers are disposed along sidewalls of a first portion of the first gate stack, and the first portion of the first gate stack is disposed on a top of the first semiconductor layer. The second gate spacers are disposed along sidewalls of a first portion of the second gate stack, and the first portion of the second gate stack is disposed on a top of the second semiconductor layer.

The first inner spacers are disposed along sidewalls of a second portion of the first gate stack, and the second portion of the first gate stack is disposed on a bottom of the first semiconductor layer. The second inner spacers are disposed along sidewalls of a second portion of the second gate stack, and the second portion of the second gate stack is disposed on a bottom of the second semiconductor layer. The first inner spacers are further disposed between the first source/drain structures and the second portion of the first gate stack, and the second inner spacers are further disposed between the second source/drain structures and the second portion of the second gate stack. The first inner spacers have a first profile, the second inner spacers have a second profile, and the first profile is different than the second profile.

In some embodiments, the first inner spacers have a first height, the first inner spacers have a first width, and the first width varies along the first height. In some embodiments, the second inner spacers have a second height, the second inner spacers have a second width, and the second height varies along the second width. In some embodiments, an oxide residue is between the first inner spacers and the second portion of the first gate stack and a silicon germanium residue is between the second inner spacers and the second portion of the second gate stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor layer stack that includes first semiconductor layers and second semiconductor layers in an interleaving pattern;
patterning the semiconductor layer stack to form a first semiconductor stack in a first device region and a second semiconductor stack in a second device region;
forming first source/drain recesses and second source/drain recesses, wherein a portion of the first semiconductor stack is disposed between the first source/drain recesses and a portion of the second semiconductor stack is disposed between the second source/drain recesses;
after forming the first source/drain recesses, recessing the second semiconductor layers of the portion of the first semiconductor stack to form first inner spacer gaps;
after forming the second source/drain recesses, replacing the second semiconductor layers of the portion of the second semiconductor stack with oxide layers and recessing the oxide layers to form second inner spacer gaps;
forming first inner spacers in the first inner spacer gaps and second inner spacers in the second inner spacer gaps; and
after forming the first inner spacers and the second inner spacers, replacing the second semiconductor layers of the portion of the first semiconductor stack with a first gate stack and the oxide layers of the portion of the second semiconductor stack with a second gate stack.

2. The method of claim 1, further comprising:
forming a first mask over the first device region when forming the first source/drain recesses and recessing the second semiconductor layers of the portion of the first semiconductor stack to form the first inner spacer gaps; and
forming a second mask over the second device region when forming the second source/drain recesses, replacing the second semiconductor layers of the portion of the second semiconductor stack with the oxide layers, and recessing the oxide layers to form the second inner spacer gaps.

3. The method of claim 1, further comprising:
wherein the replacing the second semiconductor layers of the portion of the first semiconductor stack with the first gate stack includes selectively removing the second semiconductor layers of the portion of the first semiconductor stack to form first gate gaps between the first semiconductor layers of the portion of the first semiconductor stack, forming a first gate dielectric that partially fills the first gate gaps, and forming a first gate electrode that fills a remainder of the first gate gaps, wherein the first gate dielectric and the first gate electrode provide the first gate stack in the first device region;
wherein the replacing the oxide layers of the portion of the second semiconductor stack with the second gate stack includes selectively removing the oxide layers of the portion of the second semiconductor stack to form second gate gaps between the first semiconductor layers of the portion of the second semiconductor stack, forming a second gate dielectric that partially fills the second gate gaps, and forming a second gate electrode that fills a remainder of the second gate gaps, wherein the second gate dielectric and the second gate electrode provide the second gate stack in the second device region;
forming a third mask over the second device region when selectively removing the second semiconductor layers and forming the first gate dielectric; and
forming a fourth mask over the first device region when selectively removing the oxide layers and forming the second gate dielectric.

4. The method of claim 3, further comprising forming the first gate electrode and the second gate electrode simultaneously.

5. The method of claim 1, further comprising simultaneously forming the first inner spacers and the second inner spacers.

6. The method of claim 1, further comprising separately forming the first inner spacers and the second inner spacers.

7. The method of claim 1, further comprising:
forming a first dummy gate over the first semiconductor stack and a second dummy gate over the second semiconductor stack before forming the first source/drain recesses and the second source/drain recesses; and
simultaneously removing the first dummy gate to form a first gate opening and the second dummy gate to form a second gate opening, wherein the first dummy gate and the second dummy gate are removed after replacing the second semiconductor layers of the portion of the second semiconductor stack with oxide layers and before replacing the second semiconductor layers of the portion of the first semiconductor stack with the first gate stack and the oxide layers of the portion of the second semiconductor stack with the second gate stack.

8. The method of claim 1, wherein:
the recessing the second semiconductor layers of the portion of the first semiconductor stack to form the first inner spacer gaps includes performing a first etching process having a first etch selectivity between the second semiconductor layers and the first semiconductor layers; and
the recessing the oxide layers to form the second inner spacer gaps includes performing a second etching process having a second etch selectivity between the oxide layers and the first semiconductor layers, wherein a difference between the second etch selectivity and the first etch selectivity provides the first inner spacer gaps with a first profile and the second inner spacer gaps with a second profile that is different than the first profile.

9. The method of claim 1, wherein:
the first device region is an n-type transistor region; and
the second device region is a p-type transistor region.

10. A method comprising:
forming a first multilayer stack in a first device region and a second multilayer stack in a second device region, wherein each of the first multilayer stack and the second multilayer stack includes sacrificial semiconductor layers and semiconductor layers;
removing the sacrificial semiconductor layers of the first multilayer stack to form first gaps between the semiconductor layers of the first multilayer stack;
forming sacrificial oxide layers in the first gaps;
recessing the sacrificial oxide layers to form first inner spacer notches between the semiconductor layers of the first multilayer stack;
recessing the sacrificial semiconductor layers to form second inner spacer notches between the semiconductor layers of the second multilayer stack;
after forming first inner spacers in the first inner spacer notches, removing the sacrificial oxide layers to form second gaps between the semiconductor layers of the first multilayer stack;
after forming second inner spacers in the second inner spacer notches, removing the sacrificial semiconductor layers to form third gaps between the semiconductor layers of the second multilayer stack; and
forming a first gate stack in the second gaps and a second gate stack in the third gaps.

11. The method of claim 10, further comprising:
masking the second device region when removing the sacrificial semiconductor layers of the first multilayer stack to form the first gaps, forming the sacrificial oxide layers in the first gaps, and recessing the sacrificial oxide layers to form first inner spacer notches; and
masking the first device region when recessing the sacrificial semiconductor layers to form the second inner spacer notches.

12. The method of claim 10, further comprising:
masking the second device region when removing the sacrificial oxide layers to form the second gaps and forming a first gate dielectric of the first gate stack in the second gaps; and
masking the first device region when removing the sacrificial semiconductor layers to form third gaps and forming a second gate dielectric of the second gate stack in the third gaps.

13. The method of claim 12, further comprising:
forming a first gate electrode of the first gate stack in the second gaps; and
forming a second gate electrode of the second gate stack in the third gaps.

14. The method of claim 10, wherein the forming the first inner spacers and the forming the second inner spacer includes:
depositing a dielectric material over the first device region and the second device region, wherein the dielectric material at least partially fills the first inner spacer notches and the second inner spacer notches; and
etching the dielectric material.

15. The method of claim 10, further comprising:
forming a first dummy gate over the first multilayer stack;
forming a second dummy gate over the second multilayer stack; and
removing the first dummy gate and the second dummy gate before removing the sacrificial oxide layers to form the second gaps and removing the sacrificial semiconductor layers to form the third gaps.

16. The method of claim 10, wherein:
the first inner spacer notches have a first profile; and
the second inner spacer notches have a second profile, wherein the second profile is different than the first profile.

17. The method of claim 10, wherein:
the first device region is a p-type transistor region; and
the second device region is an n-type transistor region.

18. A device structure comprising:
a p-type transistor that includes:
a first semiconductor layer disposed between first source/drain structures,
a first gate stack disposed over the first semiconductor layer, wherein the first gate stack is disposed between the first source/drain structures,
first gate spacers disposed along sidewalls of a first portion of the first gate stack, wherein the first portion of the first gate stack is disposed on a top of the first semiconductor layer, and
first inner spacers disposed along sidewalls of a second portion of the first gate stack, wherein the second portion of the first gate stack is disposed on a bottom of the first semiconductor layer and the first inner spacers are disposed between the first source/drain structures and the second portion of the first gate stack;
an n-type transistor that includes:
a second semiconductor layer disposed between second source/drain structures,
a second gate stack disposed over the second semiconductor layer, wherein the second gate stack is disposed between the second source/drain structures,
second gate spacers disposed along sidewalls of a first portion of the second gate stack, wherein the first portion of the second gate stack is disposed on a top of the second semiconductor layer, and
second inner spacers disposed along sidewalls of a second portion of the second gate stack, wherein the second portion of the second gate stack is disposed on a bottom of the second semiconductor layer and the second inner spacers are disposed between the second source/drain structures and the second portion of the second gate stack; and
wherein the first inner spacers have a first profile, the second inner spacers have a second profile, and the first profile is different than the second profile.

19. The device structure of claim 18, wherein:
the first inner spacers have a first height, the first inner spacers have a first width, and the first width varies along the first height; and
the second inner spacers have a second height, the second inner spacers have a second width, and the second height varies along the second width.

20. The device structure of claim 18, further comprising an oxide residue between the first inner spacers and the second portion of the first gate stack and a silicon germanium residue between the second inner spacers and the second portion of the second gate stack.
